(19) United States
(12) Patent Application Publication
(10) Pub. No.: US 2026/0361232 A1
(43) Pub. Date: Nov. 12, 2026

(54) HIGH SPEED SEMICONDUCTOR CHIP STACK WITH ACTIVE THERMAL MANAGEMENT

(71) Applicant: L. Pierre de Rochemont, Austin, TX (US)

(72) Inventor: L. Pierre de Rochemont, Austin, TX (US)

(21) Appl. No.: 19/667,308

(22) Filed: May 4, 2026

Related U.S. Application Data
(60) Provisional application No. 63/798,734, filed on May 2, 2025.

(51) Int. Cl. H02M 7/00; H01F 1/03; H01F 3/10; H01G 4/12; H10D 1/20; H10D 1/47; H10D 1/68; H10D 84/80; H10W 20/20

(52) U.S. Cl. CPC H02M 7/003; H01F 1/0306; H01F 3/10; H01G 4/1218; H10D 1/20; H10D 1/47; H10D 1/682; H10D 84/811; H10W 20/222

(57) ABSTRACT

Improvement of clock speeds of an integrated inverter circuits module comprising, an array of deposited resistive electro-ceramic materials of high density, ultra-low loss on a ground plane to effect thermal throttling of three dimensional stacked dies in vicinity of transmission lines with a primary coil winding of a serial electrical connection of the module and secondary coil windings configured in parallel connection to determine the performance rating of a module transformer, such that a center-tap electrical connection provides DC voltage input to the fully integrated inverter circuit, and vertical connections to the parallel wound coil secondary coil wherein electrical connections are made resonant gate power transistors formed on the additional material and additional capacitive electro-ceramic material is formed and expanding transistor integration into the dies' third dimension without performance limitation.

### CROSS REFERENCE TO RELATED APPLICATIONS

This application claims priority to U.S. Provisional Patent Application No. 63/798,734, filed May 2, 2025, the contents of which is incorporated by reference herein in its entirety and for all purposes.

### FIELD OF THE INVENTION

The present invention relates generally to the design and construction of a three dimensional (3D) stack of semiconductor die (chips) that improves system clock speeds of the assembled integrated circuits by using ultra-low loss, high dielectric density materials within the vicinity of interconnecting transmission lines and provides the means to actively cool semiconductor die embedded within the system to prevent thermal throttling of the semiconductor die's intrinsic clock speed.

The present invention further relates to quality improvements to Big Nano thermoelectric devices in direct thermal contact with the actively cooled semiconductor die.

An aspect of the present invention relates to the use of the improved quality thermoelectric devices in applications related to the recapture of waste heat energy and its conversion into electrical power.

The present invention additionally relates to the use of improved quality Big Nano thermoelectric devices in stacked chip assemblies to expand transistor integration into the third dimension without performance limitation.

### 1. BACKGROUND TO THE INVENTION

Moore's Law enabled transistor densities to grow exponentially for decades, increasing the computational power that can be integrated into a square centimeter of semiconductor real estate. This trend lowered microelectronic manufacturing cost and power consumption. Unfortunately, the industry is reaching its limit on the number of transistors that can be integrated within a 2D plane of semiconductor real estate. Greater transistor densities can be achieved by expanding transistor integration into the third or vertical dimension as shown in FIG. 1A. As is similar in land real estate markets, this would allow semiconductor manufacturer to pack more economic value into every square centimeter of semiconductor real estate. There are several challenges to assembling across design, manufacturing and reliability that include:
i Die Dimensions and Alignment
   Variations in height, area and bump density make bonding difficult, especially as the number of stacked die increases.
ii Placement accuracy
   Advanced bonding methods, such as hybrid bonding, require extremely precise placement of dies in x, y and theta directions and misalignment can lead to assembly defects.
iii Thermal Management
   Each die generates heat and stacked configurations exacerbate thermal issues. Effective cooling solutions, like heat sinks and interposers are essential to prevent overheating and thermal throttling.
   In densely packed stacks, heat transfer between dies (thermal crosstalk) can degrade performance and reliability.
iv Mechanical Stability
   Differences in die height and materials cause warpage during assembly impacting yield and long-term reliability.
   Stacked configurations add and mechanical strain, requiring innovative materials to manage induced stress to maintain mechanical stability.
v Signal Integrity
   Multi-layered circuitry demands precise routing to avoid signal degradation or interference (crosstalk) between semiconductor die/
   Ensuring reliable electrical interconnections between die is challenging and tight tolerance electrical components and interconnections.
vi Thermal Throttling
   Thermal throttling is a protective mechanism in CPUs and GPUs to prevent heat-related damage by reducing clock speeds when the component temperature approaches critical levels, such as the components' their thermal limit, typically between 90-105 °C
   Lowers intrinsic (die) clock speeds decrease heat generation and impact system performance causing lag or frame rates to drop. Therefore, optimal semiconducting stack solutions will provide active cooling (thermal management) with the stacked die assembly
vii Manufacturing Complexity
   Dies sourced from different foundries are likely to have varying specifications, increasing manufacturing complexity and cost
   Multi-die assembly processes face higher yield losses due to defects arising from dimensional mismatches and bonding errors (yield losses).
vii Limited Repairability
   Stacked configurations make repairing defective dies difficult, increasing the stakes using known good ties (KGD) during assembly
vii Cost Implications
   Advanced equipment and materials required for precise placement, bonding, and cooling significantly increase production costs

Therefore innovative means that address these challenges to provide optimal solutions with respect to materials manufacturing reliability, bonding methods, cooling systems, and design processes to balance performance, reliability, and cost in multi-die semiconductor assemblies hold great commercial value.

### 2. OVERVIEW OF THE RELATED ART

FIGS. 1A, 1B, 1C depict a high-speed semiconductor chip stack 1 per de Rochemont, “HIGH SPEED SEMICONDUCTOR CHIP STACK”, U.S. Ser. No. 15/969,234('234) that comprises a bonded stacked assembly 3 of semiconductor die 5 and/or interposers 7 vertically mounted on a major surface of a substrate 9, wherein the bonded stacked assembly 3 further comprises thru vias 11 that provide an electrical interface between the layered integrated components within the high-speed chip stack 1. Interposers 7 are electrical interconnects formed on semiconductor substrates that contain no active electronic circuitry (transistors or diodes). The chip stack 1 may also comprise a heterogeneous assembly of semiconductor die 13 and passive elements 15 (resistors, capacitors, inductors) mounted or formed on the top of the semiconductor chip stack 1 as surface features 17. Passive element surface features 17 may also be integrated on semiconductor die 5 and interposers 7.

A key characteristic of the high-speed semiconductor chip stack 1 is that it comprises electrical interconnects further comprising amorphous silica dielectric, high conductivity electrodes and passive circuitry additionally comprising high chemical complexity electroceramic having nanoscale microstructure 19. High chemical complexity electroceramic having nanoscale microstructure 19 that comprises a uniform distribution of ceramic grains 21 with identical chemistry and grain size ≤50 nm 23. The high chemical complexity electroceramic have nanoscale microstructure 19 may further comprise amorphous silica grains boundaries 25 having maximal resistivity (10⁻¹⁸ Ω-cm) to increase breakdown voltages and to stop leakage currents 27 through capacitive elements. Nanoscale electroceramic microstructures suppress ion transport mechanisms within capacitive electroceramic that affect performance value variance with temperature, frequency, applied voltage, and time (aging). Embedding capacitive elements comprising electroceramic having nanoscale electroceramic microstructure 19 as impedance matching tuning elements within transmission lines further comprising amorphous silica dielectric enables stable impedance matching through tera-hertz frequency domains to enable ultra-high speed chip stacks, wherein the system speed of the stacked assembly matches the maximal intrinsic clock speeds of the semiconductor chips assembled within the chip stack.

The high chemical complexity, comprising ≥3 atomic elements, increases dielectric performance values to levels that miniaturize component size. Smaller component size enables higher frequency signals to be designed into the chip stack under the “Lumped Circuit Approximation”, under which instantaneous fields within the component no longer have to be accounted for. It applies when the size of components is less that 1/20th the size of the operating signal wavelength. In general higher complexity electroceramic materials have higher performance values, and thus enable greater component size miniaturization. It is thus preferable to incorporate electroceramic dielectrics comprising 4 or more atomic elements to maximize the degree of component miniaturization of surface elements.

The minimization of electroceramic polarization rates is another key feature of high-speed semiconductor chip stacks 1. Capacitive dielectric having nanoscale microstructure 19 wherein all grains 21 have uniform grain size 23 that is less than or equal to 50 nm will only exhibit dielectric polarization through the deformation of atomic orbitals, which respond on femto-second time scales. Polarization modes relating to ionic transport, and other, mechanisms are suppressed. These other polarization mechanisms respond at rates greater than 0.1 nanoseconds (100 s of picoseconds), and will introduce phase noise at signal frequencies operating in the low giga-hertz (GHz) regime. While the high-speed semiconductor chip stack 1 addresses many of the packaging limitations that prevent the system clock speed of that stacked chip assembly 3 from operating at higher clock speed, it does not provide means to address thermal throttling of semiconductor die embedded within a stacked chip package when component temperatures rise to levels of 90 °C to 105 °C. Therefore, a high-speed semiconductor chip stack enabling maximal intrinsic semiconductor clock speeds by providing means for active thermal management is desirable.

Embedding miniaturized passives within the I/O link minimizes stub lengths to maximize bandwidths. Typically, terminating passive components 28 are arrayed around the periphery of a heterogeneous chip assembly 30 as depicted in FIG. 1D. The heterogeneous chip assembly 30 is completed by mounting the stacked memory chip assemblies 32 and heat-generating semiconductor die 34 on a first passive interconnection substrate 36, which, in turn, is mounted on a second passive interconnection substrate 38 to provide electrical communication with the terminating passives components 28. This configuration of terminating passive leads to excessively long stub lengths 40 in the input/output (I/O) channels that connect stacked memory chips 34 to heat-generating processor die 36 because the electrical interconnections forming the I/O channels have to run from the stacked memory chip assembly 32 through the first 36 and second 38 passive interconnection substrates to reach the terminating passive components 28 before a reliable electrical connection can be made to the heat-generating semiconductor die 34. This configuration which imposes long stub-lengths 40 limits the data rates that flow within the I/O channels which restricts I/O bandwidths in the heterogeneous chip assembly 30. de Rochemont '234 teaches methods to miniaturize passive component size to locate them within vias and along I/O channel transmission lines to minimize stub lengths and allow clock speeds in the tera-hertz (THz) frequency domain to run through the chip stack, which would I/O data bandwidths by orders of magnitude. However, de Rochemont '234 is silent on means to provide active thermal management to remove hot spots in the vertical chip stack assembly 102 comprising heat generating semiconductor die 34. The heat generated by these semiconductor die causes thermal throttling that lowers the intrinsic clock speeds of semiconductors, so even if the assembled structure can accommodate significantly higher clock speeds without distortive effects, the heat-generating semiconductor die 34 become the limiting factor. Therefore, means to provide active thermal management that cools the heat generating semiconductor die 34 and prevents thermal throttling is a valuable development.

FIGS. 2A, 2B, 2C depict 3D quantum gas material deployed as a thermoelectric body 29 (29A,29B) comprising a uniform distribution of equally sized semiconductor grain cores 31 having a grain size diameter 33 in the range of 10-100 nm. Means providing electrical and thermal insulation 39 are situated between n-type 29A and p-type 29B thermoelectric bodies. Each semiconductor grain core 31 is fully enveloped by a distinct grain boundary material 35 having a thickness ranging from 10-20 nm and the grain boundary material 35 consists of an alkali metal (selected from Column I of the Periodic Table of the Elements) or an alkaline Earth metal (selected from Column II of the Periodic Table of the Elements). Schottky barriers are potential energy barriers for electrons that form at metal-semiconductor junctions. The height of the potential energy barrier, Φ_{B} 37 at the metal-semiconductor junction enveloping each semiconductor grain core 31 is approximately equal to the difference between the enveloping metal's work function and the grain core's 31 semiconductor's electron affinity. These potential energy differences are illustrated in FIG. 2B. In this instance, the nanoscale microstructure of the thermoelectric body 29 causes the electron states within the semiconductor gain cores 31 to be quantized by the potential energy barriers 37 created by enveloping metallic grain boundary material 35. This quantization process causes electrons to occupy discrete energy states 39 with 3D quantum wells 41 within the semiconductor grains 30. Quantized wave functions 42 that denote the probability of finding an electron at specific locations within the 3D quantum well 41 have wave functions tails 44 that penetrate into regions of the potential energy barriers 37. Overlapping wave function tails 44 of quantized wave functions 42 for quantized electron states within adjacent 3D quantum wells 40 enable quantum tunneling processes that effortlessly transfer electrons through the potential energy barriers 37 between the adjacent quantum wells 41. This nanoscale microstructure enables the thermoelectric body 29 to effortlessly transfer electron currents 46 through quantum tunneling processes across its bulk dimensions, whereas phonons, p, that represent vibrational quanta are strongly scattered at every grain boundary that comprises chemically distinct materials 35.

zT are the parameters that establish a thermoelectric figure of merit, where

$$z = \frac{σ {S}^{2}}{κ} \qquad ( 1 )$$

and T is the temperature, τ is the electrical conductivity, S is the materials and temperature dependent Seebeck Coefficient, and K is the thermal conductivity. Thermal conductivity, κ consists of two components,

κ=κ_{electron}+κₚₕₒₙₒₙ (2)

κ_{electron} represents heat conduction contributed by the flow of electrons, while κₚₕₒₙₒₙ represents heat conduction mechanisms mediated by the flow of phonons, or quanta of the lattice vibrations in the conducting medium. Until recently, maximal thermoelectric figures of merit were equivalent to ⅙th the value of vapor compression refrigeration system. Simple inspection of equation (1) reveals that that semiconductors with minimal κₚₕₒₙₒₙ from phonon transport mechanisms akin to the strong scattering found in a glassy medium and the high electrical conductivity, σ, commensurate with the minimal electron scattering found in crystalline medium, are needed to improve thermoelectric figure of merit zT.

As shown in FIG. 2A, semiconductors comprising nanoscale microstructures further comprising semiconducting grain cores 31 fully enveloped by grain boundary materials 35 consisting of chemically distinct materials that strongly scatter phonons 48 at each grain boundary-grain core interface to quench phonon mediated thermal currents, κₚₕₒₙₒₙ to optimize thermoelectric figures of merit by allowing electrical currents 46 to flow effortlessly through quantum tunneling mechanisms within the thermoelectric body 29.

As depicted in FIGS. 2C,2D a thermoelectric circuit 50 comprises electrodes 52 that provide serial electrical communication between alternating n-type thermoelectric bodies 29A and p-type thermoelectric bodies 29B laid out as an elemental array on a thermal surface 54. When a temperature differential is applied across opposite major surfaces 56A,56B of the thermoelectric circuit 50, electrical currents (power generation) will flow through the electrodes and stored with an energy storage device connected to the electrodes 52. When an electrical current is passed through the electrodes 52, heat will be pumped from one major surface 56A to the other major surface 56B through the n-type 29A and p-type 29B thermoelectric bodies. The thermoelectric circuit 50 additionally comprises electrically insulating means 58 between n-type thermoelectric bodies 29A and p-type thermoelectric bodies 29B. FIG. 2D illustrates a thermoelectric circuit in three dimensions where some electrodes 52 that electrically connect n-type 29A and p-type 29B thermoelectric bodies and the means providing electrical and thermal insulation 29 are not show and the for illustrative simplicity. Insulating means 45 is used to electrically isolate n-type thermoelectric bodies 29A from p-type thermoelectric bodies 29B to direct current and voltages through the electrodes 52. Insulating means 45 may comprise thermally insulating amorphous silica or thermally conducting aluminum nitride.

Thermoelectric circuits 50 may comprise a plurality of independent thermoelectric circuits 58 and 60 that consist electrodes 52 that electrically interconnect in series alternating n-type 29A to alternating p-type 29B of thermoelectric bodies that are configured within a single column (or row) 58 within the elemental array, or electrically interconnect alternating n-type 29A to alternating p-type 29B thermoelectric bodies in series that are configured across a plurality columns and rows 60 of the elemental array. Each thermoelectric circuit has input/output electrodes 53 through which electrical currents are supplied to function as heat pump drivers or to conduct electrical power generated by the heat differentials applied to the major surfaces 56A,56B for energy storage. Thermoelectric circuit(s) 50 are in direct thermal contact with a thermal surface 64 whose temperature it regulates.

The location of terminating passive elements and the materials used in their construction is a further challenge to making high performance chip stacks. As depicted in

de Rochemont U.S. Pat. No. 7,405,698 entitled “CERAMIC ANTENNA MODULE AND METHODS OF MANUFACTURE THEREOF” (the '698 application) discloses the use of high permittivity electroceramic to form transmission lines that have characteristic impedance that matches the input/output impedance of a semiconductor chip, and the integration of those transmission lines on the surface of a semiconductor die or electrical interconnect (interposer), but it does not disclose art related to transmission lines that comprise high permittivity and high permeability dielectrics configured along the path of a transmission line that causes the transmission line to resonate a given frequency or desired clock speed, nor does it disclose the incorporation of high permittivity transmission lines within a chip stack 1.

de Rochemont U.S. Ser. No. 11/479,159, filed Jun. 30, 2006, entitled “ELECTRICAL COMPONENT AND METHOD OF MANUFACTURE” (the '159 application) discloses and claims high permittivity electroceramics that by virtue of having uniform nanoscale grain size and microstructure exhibits dielectric permittivity that remains stable over standard operating temperatures. It also discloses the incorporation of those high permittivity electroceramics within a capacitor that is formed on the surface of a semiconductor die, an electrical interconnect (interposer), or within a printed circuit board, but it does not disclose its application to semiconductor chip stacks.

The present invention is illustratively described above in reference to the disclosed embodiments. Various modifications and changes may be made to the disclosed embodiments by persons skilled in the art without departing from the scope of the present invention as defined in the appended claims.

This application incorporates by reference all matter contained in de Rochemont U.S. Pat. No. 7,405,698 entitled “CERAMIC ANTENNA MODULE AND METHODS OF MANUFACTURE THEREOF” (the '698 application), de Rochemont U.S. Pat. No. 8,715,839 filed Jun. 30, 2006, entitled “ELECTRICAL COMPONENT AND METHOD OF MANUFACTURE” (the '839 application), de Rochemont U.S. Pat. No. 8,350,657 (the '657 application), filed Jan. 6, 2007 entitled “POWER MANAGEMENT MODULE AND METHODS OF MANUFACTURE”, de Rochemont U.S. Ser. No. 14/560,935, (the '935 application), filed Dec. 4, 2014 entitled “POWER MANAGEMENT MODULE AND METHODS OF MANUFACTURE”, de Rochemont and Kovacs, U.S. Pat. No. 8,715,814, “LIQUID CHEMICAL DEPOSITION PROCESS APPARATUS AND EMBODIMENTS”, (the '814 application) and U.S. Pat. No. 8,354,294 (the '294 application), de Rochemont, “MONOLITHIC DC/DC POWER MANAGEMENT MODULE WITH SURFACE FET”, U.S. Pat. No. 8,552,708 (the '708 application), de Rochemont, U.S. Pat. No. 8,749,054, “SEMICONDUCTOR CARRIER WITH VERTICAL POWER FET MODULE”, (the '054 application), de Rochemont U.S. Pat. No. 9,023,493, “CHEMICALLY COMPLEX ABLATIVE MAX-PHASE MATERIAL AND METHOD OF MANUFACTURE”, (the '493 application), de Rochemont U.S. Pat. Nos. 8,779,489 and 9,153,532, “POWER FET WITH A RESONANT TRANSISTOR GATE”, (the '489 and '532 application), de Rochemont U.S. Pat. No. 9,123,768, “SEMICONDUCTOR CHIP CARRIERS WITH MONOLITHICALLY INTEGRATED QUANTUM DOT DEVICES AND METHOD OF MANUFACTURE THEREOF”, (the '768 application), de Rochemont U.S. Pat. No. 8,952,858, “FREQUENCY-SELECTIVE DIPOLE ANTENNAS”, (the '858 application), de Rochemont and Kovacs U.S. Pat. No. 9,348,385, “HYBRID COMPUTING MODULE” (the '385 application), de Rochemont, “FULLY INTEGRATED THERMOELECTRIC DEVICES AND THEIR APPLICATION TO AEROSPACE DE-ICING SYSTEMS”, U.S. Application No. 61/529,302 ('302). de Rochemont, “RESONANT HIGH ENERGY DENSITY STORAGE DEVICE”, U.S. Ser. No. 15/958,706 ('706), de Rochemont, “HIGH SPEED SEMICONDUCTOR CHIP STACK”, U.S. Ser. No. 15/969,234 ('234), de Rochemont, “HIGH SPEED/LOW POWER FARMS AND SERVER NETWORKS”, U.S. Ser. No. 16/403,411 ('411), and de Rochemont, “MODULE WITH HIGH PEAK BANDWIDTH I/O CHANNELS”, U.S. Ser. No. 16/432,691 ('691).

The '698 application instructs on methods and embodiments that provide meta-material dielectrics, including artificial magnetic ground planes, that have dielectric inclusion(s) with performance values that remain stable as a function of operating temperature. This is achieved by controlling the dielectric inclusion(s)' microstructure to nanoscale dimensions less than or equal to 50 nm. de Rochemont '839 instructs the integration of passive components that hold performance values that remain stable with temperature in printed circuit boards, semiconductor chip packages, wafer-scale SoC die, and power management systems. de Rochemont '159 instructs on how LCD is applied to form passive filtering networks and quarter wave transformers in radio frequency or wireless applications that are integrated into a printed circuit board, ceramic package, or semiconductor component. de Rochemont '657 instructs methods to form an adaptive inductor coil that can be integrated into a printed circuit board, ceramic package, or semiconductor device. de Rochemont et al. '814 discloses the liquid chemical deposition (LCD) process and apparatus used to produce macroscopically large compositionally complex materials, that consist of a theoretically dense network of polycrystalline microstructures comprising uniformly distributed grains with maximum dimensions less than 50 nm. Complex materials are defined to include semiconductors, metals or super alloys, and metal oxide ceramics. de Rochemont '858 instructs means to form a circuit resonant element by folding arms of dipole antenna or transmission line to induce inductive and capacitive loads through current vector coupling. de Rochemont '814 and '708 instruct on methods and embodiments related to a fully integrated low EMI, high power density inductor coil and/or high power density power management module. de Rochemont '489 and '532 instruct on methods to integrate a field effect transistor that switches arbitrarily large currents at arbitrarily high speeds with minimal On-resistance into a fully integrated silicon chip carrier. de Rochemont '768 instructs methods and embodiments to integrate semiconductor layers that produce a 3-dimensional electron gas within semiconductor chip carriers and monolithically integrated microelectronic modules. de Rochemont '302 instructs methods and embodiments to form thermoelectric device performance by integrating chemically complex polycrystalline semiconductor grain cores that have uniform grain size ranging between 10-100 nm in diameter and are fully enveloped by distinct grain boundary material comprising a metallic material comprising an alkali or alkaline Earth metal. de Rochemont '302 does not instruct means to optimize the energetic potential barrier formed at the electrical junction between the semiconductor grain core 31 and the metallic grain boundary material 35 enveloping the grain core 31 by forming metallic grain boundary material 35 that comprises an alloy or superalloy of alkali elements or alkaline Earth elements. The various embodiments and means claimed in the present application are constructed using liquid chemical deposition (LCD) methods instructed by de Rochemont et al. '814.

LCD methods permit the integration of high chemical complexity semiconductors and alloys or superalloys on a buried microelectronic layer with the requisite chemical precision to make the finished product(s) economically viable. It enables chemically complex electroceramics to be selectively deposited on a semiconductor surface at temperatures that do not damage embedded active circuitry. It further enables the integration of chemically complex electroceramics with atomic scale chemical uniformity and uniform microstructure, including microstructure that has nanoscale uniformity irrespective of electroceramic chemical complexity.

### 3. DEFINITION OF TERMS

The term “average amu” is herein understood to mean the median atomic mass of a unit cell for a crystalline compound derived by summing the fractional atomic mass units contributed by elements forming the crystal lattice.

The terms “chemical complexity”, “compositional complexity”, “chemically complex”, or “compositionally complex” are herein understood to refer to a material, such as a metal or superalloy, compound semiconductor, or ceramic that consists of three (3) or more elements from the periodic table.

The term “chip stack” is herein understood to mean a bonded three dimensional (3D) assembly of chips that may comprise semiconductor die and non-semiconductor chip elements, such as sensors, micro-electromechanical systems (“MEMS”), and/or interposer circuits that provide passive electrical interconnections or thermal management between the various components in the 3D assembly.

The term “critical performance tolerances” is herein understood to refer to the ability for all passive components in an electrical circuit to hold performance values within D 1% of the desired values at all operating temperatures over which the circuit was designed to function.

The term “electroceramic” is herein understood to refer to its conventional meaning as being a complex ceramic material that has robust dielectric properties that augment the field densities of applied electrical or magnetic stimulus.

The term “integrated circuit” (or “IC”) is herein understood to mean a semiconductor chip into which a large, very large, or ultra-large number of transistor elements have been embedded.

The term “liquid chemical deposition” (or “LCD”) is herein understood to mean a method that uses liquid precursor solutions to fabricate materials of arbitrary compositional or chemical complexity as an amorphous laminate or free-standing body or as a crystalline laminate or free-standing body that have atomic-scale chemical uniformity and a microstructure that is controllable down to nanoscale dimensions.

The term “MAX-phase material” is herein understood to define a chemically complex intermetallic ceramic material having the general chemical formula M₍ₙ₊₁₎AXₙ, wherein M is first row transition-metal element, A is an “A-group” element found in columns III-VI of the periodic table, and X is either carbon (C) or nitrogen (N).

The term “microstructure” is herein understood to hold its traditional meaning of relating to the grain size, grain chemistry, and grain boundary chemistry of a polycrystalline ceramic material.

The term “passive component” is herein understood to refer to its conventional definition as an element of an electrical circuit that that modulates the phase or amplitude of an electrical signal without producing power gain.

The term “physical layer” is herein understood to understood to mean a patterned or unpatterned material layer embedded within a microelectronic circuit wherein the material possesses some unique physical property that enhances the proper function of the circuit or a circuit element.

The term “resonant gate transistor” is herein understood to refer to any of the transistor architectures disclosed in de Rochemont, U.S. Ser. No. 13/216,192, “POWER FET WITH A RESONANT TRANSISTOR GATE”, wherein the transistor switching speed is not limited by the capacitance of the transistor gate, but operates at frequencies that cause the gate capacitance to resonate with inductive elements embedded within the gate structure.

The term “standard operating temperatures” is herein understood to mean the range of temperatures between −40 °C and +125 °C.

The term “surface feature” is herein understood to mean one or more patterned physical layers integrated on the surface of a substrate wherein the patterns and physical properties of the physical layers are designed to serve some functional purpose within a microelectronic circuit.

The term “thermoelectric effect” is herein understood to refer to its conventional definition as the physical phenomenon wherein a temperature differential applied across a material structure induces a voltage differential within that material, and/or an applied current run through the semiconductor material structure induces a temperature differential within that material structure.

The term “thermoelectric material” is herein understood to refer to its conventional definition as a solid state material structure that exhibits the “thermoelectric effect”.

The term “thermomechanical” is herein understood to refer to its conventional definition as relating to properties induced or created by the simultaneous application of elevated temperature and mechanical force or pressure.

The term “thinned” is herein understood to refer to an interposer, a sensor chip, or a semiconductor die that has been ground and chemical mechanically polished to reduce its original thickness to a lesser thickness, preferably a thickness on the order of 25 μm or less.

The term “thru via” or “via” is herein understood to refer to its conventional definition as relating to a vertical electrical connection that is made by filling a thru hole with an electrically conductive substance.

The terms “tight tolerance” or “critical performance tolerance” are herein understood to mean a performance value, such as a capacitance, inductance, or resistance that varies less than +1% over standard operating temperatures.

The term “transmission line” is herein understood, for the specific purpose of this application, to refer to any of the following: a microstrip, a stripline, ground-cladded stripline, ground-cladded dielectric waveguide, and a dielectric slab waveguide.

The term “II-VI compound semiconductor” is herein understood to refer to its conventional meaning describing a compound semiconductor comprising at least one element from column IIB of the periodic table including: zinc (Zn), cadmium (Cd), or mercury (Hg); and, at least one element from column VI of the periodic table consisting of: oxygen (O), sulfur (S), selenium (Se), or tellurium (Te).

The term “III-V compound semiconductor” is herein understood to refer to its conventional meaning describing a compound semiconductor comprising at least one semi-metallic element from column III of the periodic table including: boron (B), aluminum (Al), gallium (Ga), and indium (In); and, at least one gaseous or semi-metallic element from the column V of the periodic table consisting of: nitrogen (N), phosphorous (P), arsenic (As), antimony (Sb), or bismuth (Bi).

The term “IV-IV compound semiconductor” is herein understood to refer to its conventional meaning describing a compound semiconductor comprising a plurality of elements from column IV of the periodic table including: carbon (C), silicon (Si), germanium (Ge), tin (Sn), or lead (Pb).

The term “IV-VI compound semiconductor” is herein understood to refer to its conventional meaning describing a compound semiconductor comprising at least one element from column IV of the periodic table including: carbon (C), silicon (Si), germanium (Ge), tin (Sn), or lead (Pb); and, at least one element from column VI of the periodic table consisting of: sulfur (S), selenium (Se), or tellurium (Te).

### SUMMARY OF THE INVENTION

The present invention incudes, inter alia, a fully integrated inverter module comprising a ground plane connection, an array of resistive electroceramics selectively deposited on the ground plane connection, an overlay of amorphous silica covering the phonons array of resistive elements and partially covering the ground plane connection that is polished to expose the selectively deposited array of resistive electroceramics and to create a smooth surface on the amorphous silica insulator with the array of electroceramic resistive elements such that additional semiconductor material can be deposited thereon to form power transistors.

It further comprises vertical electrical connections through an additional amorphous silica layer separating the ground plane from a toroidal enter-tapped transformer coil wherein the primary coil winding are wound serial electrical connection and the secondary coil windings are configured in parallel connection to determine the performance rating of the transformer, such that the center-tap electrical connection provides DC voltage input to the fully integrated inverter circuit, and vertical connections to the parallel would coil secondary oil make electrical connection to the inverter module output, wherein electrical connections are made Resonant Gate Power Transistors formed on the additional material. Additional capacitive electroceramic material is formed on the overlay of amorphous silica insulator and electrically conductive elements provide electrical connection between the capacitive electroceramic, the resistive electroceramic, and the Resonant Gate Power Transistors to form the Inventor Module's Wiggler Circuit.

### BRIEF DESCRIPTION OF THE DRAWINGS

The present invention is illustratively shown and described in reference to the accompanying drawings, in which:

FIGS. 1A, 1B, 1C, 1D depicts prior art relating to high-speed semiconductor chip stacks.

FIGS. 2A, 2B, 2C, 2D depict prior art relating to thermoelectric circuits comprising thermoelectric bodies having nanoscale microstructure that induces 3D quantum wells within p-type or n-type semiconducting bodies.

FIG. 3A, 3B depict a high-speed chip stack with active thermal management.

FIGS. 4A, 4B, 4C, 4D, 4E depict general features of a high speed semiconductor chip stack with active thermal management and its methods of construction.

FIG. 5 illustrates means to mechanically stabilize a high speed semiconductor chip stack with active thermal management by incorporating mechanical constraints within thermal shunts used to cool heat generating semiconductor die.

FIGS. 6A, 6B, 6C, 6D, 6E, 6F, 6G, and 6H illustrate means to ensure high signal integrity within a high-speed semiconductor chip stack with active thermal management.

FIGS. 7A, 7B, 7C illustrate means and methods to form high thermopower thermoelectric bodies to minimize thermal throttling within a high-speed semiconductor chip stack with active thermal management.

FIGS. 8A, 8B depict the use of embedded thermocouples to actively regulate the temperature with the high-speed semiconductor chip stack.

FIGS. 9A, 9B, and 9C illustrate a restructured supply chain to minimize cost and restore growth enabling performance in microelectronic markets.

FIG. 10 illustrates the scope of this application.

FIGS. 11A, 11B respectively show Coefficients of Thermal Expansion and Properties of Constraining Members.

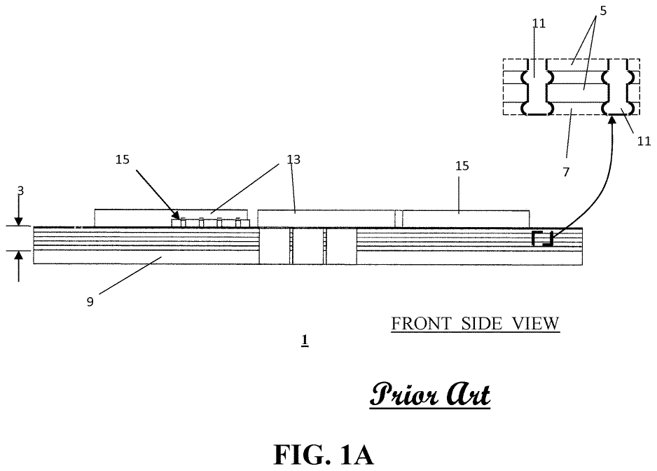

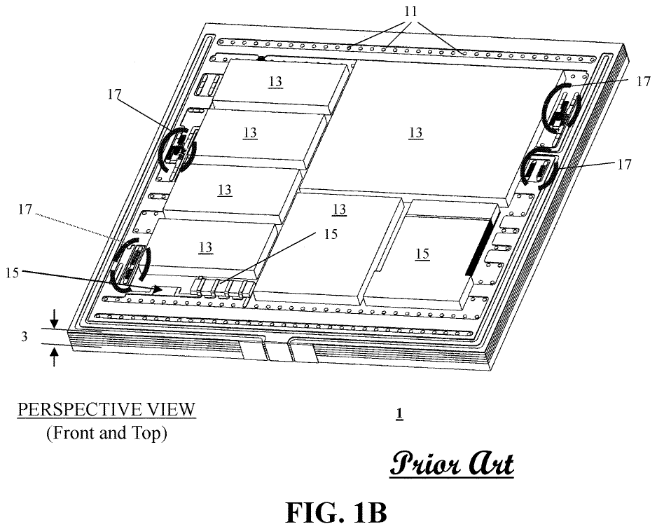

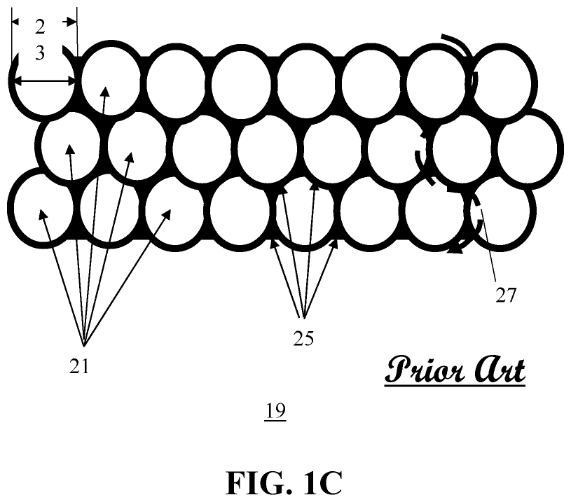

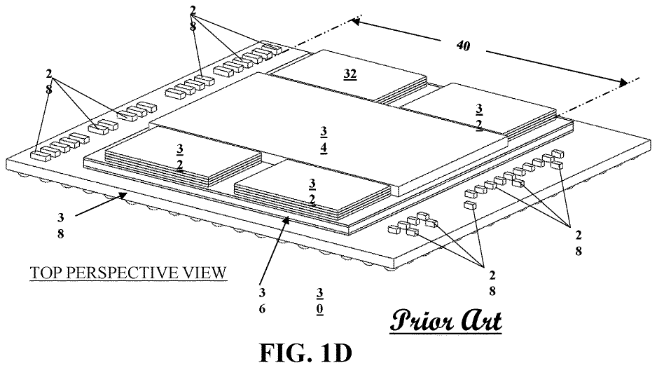

### DESCRIPTION OF THE PREFERRED EMBODIMENTS

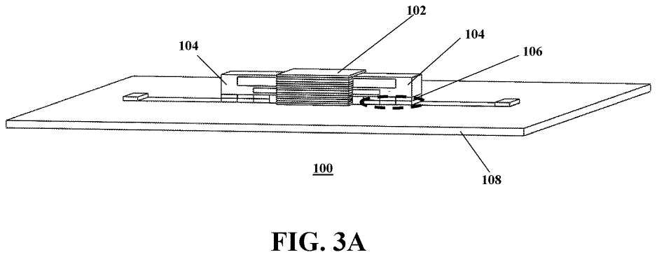

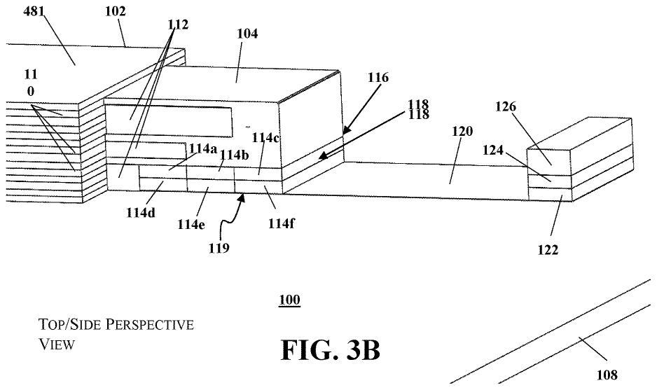

Reference is now made to FIG. 3A, 3B to illustrate means to provide active thermal management within a high-speed semiconductor chip stacks and methods that address challenges with the fabrication of semiconductor chip stacks relating to:
i) Placement Accuracy
ii) Thermal Management
iii) Mechanical Stability
iv) Signal Integrity
v) Thermal Throttling,
   and,
vi) Cost Implications.

The high-speed chip stack with active thermal management 100 comprises a vertical stacked assembly 102 comprising a plurality of semiconductor die, interposers with integrated passive networks, and thermoelectric circuit layers that actively monitor and transfer excess waste heat to thermal shunts 104 in thermal communication with a bank of thermoelectric circuits 106. All elements in the vertical stack are either mounted or formed on a substrate 108, preferably a semiconductor carrier or a substrate comprising a chemically complex glassy material, which provides mechanical stability and electrical communication between the vertical stacked assembly 102 and other elements of the larger electronic system.

The high-speed chip stack with active thermal management 100 further comprises thermal relief layers 110 embedded within the vertical stacked assembly 102 that are in thermal contact with the thermal shunts 104 that transfer waste heat energy out of the stack. Insulating means 112, preferably amorphous silica thermal insulator, are embedded within the thermal shunts 104 to prevent heat directed through the thermal shunts 104 to leak back to the vertical stack assembly 102. Thermal shunt 104 material preferably comprises silver or an alloy or superalloy comprising silver, gold, nickel, platinum, aluminum or copper having thermal conductivity greater than or equal to 300 Watts-m⁻¹-K⁻¹ and is optimized to improve mechanical stability of the vertical stack assembly 102.

As shown below the thermal relief layer 110 receives waste heat pumped by thermoelectric circuits embedded within the stacked assembly 102 from heat generating semiconductor die. Thermal shunts 104 transfer the waste heat to the bank of thermoelectric circuits 106 that comprise one or more waste heat energy recovery thermoelectric circuits 114a,114b,114c,114d,114e,114f, wherein thermoelectric circuits 114a,114b,114c are configured to provide a cold thermal surface 116 to the thermal shunts 104 and additional thermoelectric circuits 114d,114e,114f are configured for maximal waste heat energy recovery converting the waste heat energy collected between the hot interface 118 and the cold interface 119 into electrical power that is either recycled within the stacked assembly 102 or stored for future use. The cold interface is in thermal communication with a thermal heat sink trace 120 formed on the substrate 108 preferably comprising silver or an alloy or a superalloy comprising silver, gold, nickel, platinum, aluminum or copper having thermal conductivity greater than or equal to 300 Watts-m⁻¹-K⁻¹. The thermal heat sink trace 120 is in thermal contact with a regulating thermoelectric circuit 122 configured to regulate the temperature of the thermal heat sink trace 120 to maximize the conversion of thermal waste heat energy to electrical power through additional thermoelectric circuits 114d,114e,114f. Since cold temperatures are provided to thermal heat sink trace 120 by regulating thermoelectric circuit 122, high temperatures will be directed to the opposing major surface of the regulating thermoelectric circuit 122. That heat may be used to capture additional waste heat energy generated by regulating thermoelectric circuit 122 and converted it into electrical power through supplemental waste heat conversion thermoelectric circuit 124 that is in thermal contact with a heat sink 126.

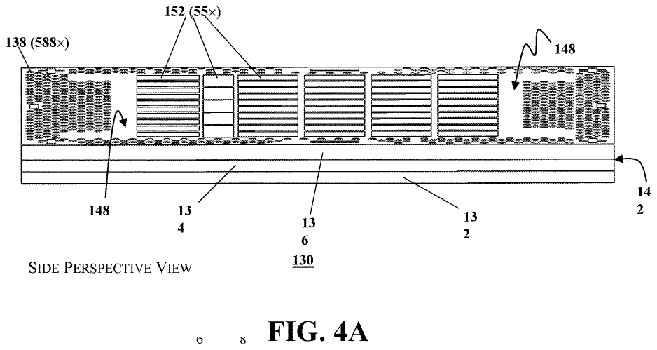

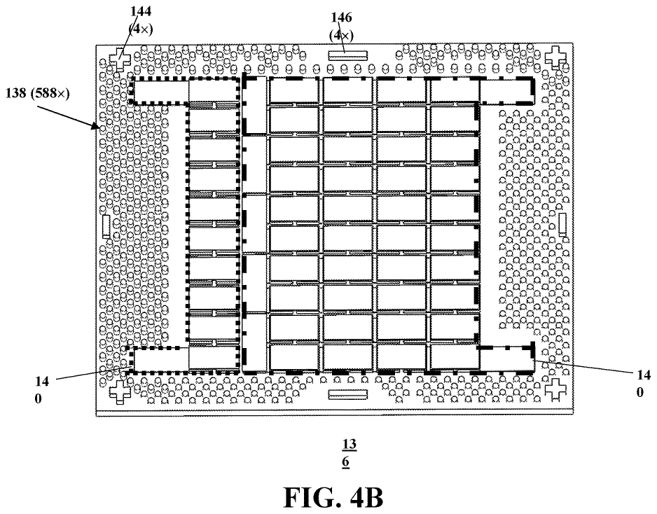

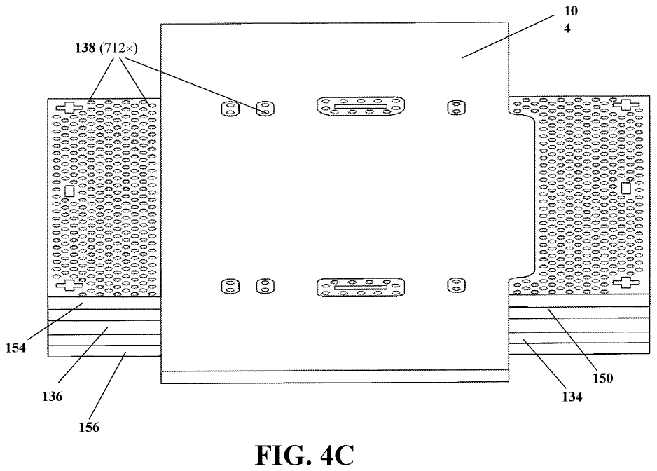

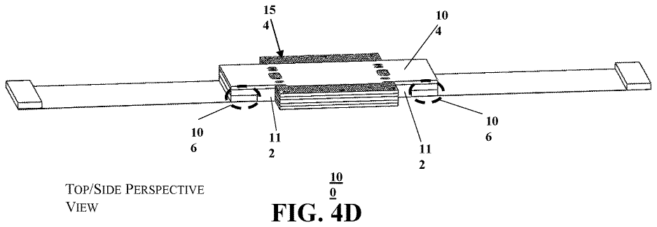

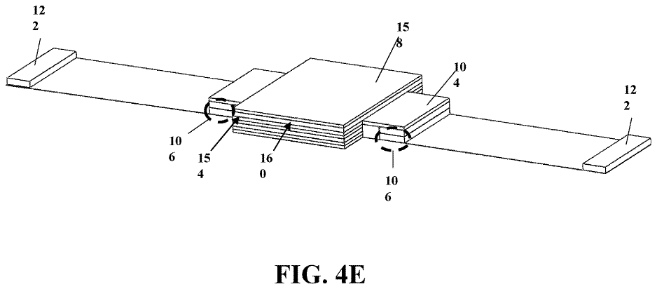

Reference is now made to FIGS. 4A, 4B, 4C, 4D, 4E, 4F, 4G and 4H that illustrate the means to fabricate high-speed semiconductor chip stacks with active thermal management. FIG. 4A,4B depict the base layers of a high-speed semiconductor chip stack with active thermal management 130 that comprises a heat generating semiconductor die 132 preferably a thinned semiconductor die, that makes electrical connection through a first high-speed interposer 134, preferably a thinned high-speed interposer, to a thermoelectric circuit layer 136. The first (thinned) high-speed interposer 134 reconfigures the I/O pin layout on the top of the thinned semiconductor die 132, so they mate with the thru vias 138 in the thermoelectric circuit layer 136. The thermoelectric circuit layer 136 comprises at least one thermoelectric circuit 140 that pumps heat generated by the heat generating semiconductor die 132 through the first (thinned) high-speed interposer 134 from the thermal surface 142 located at the planar interface between the first high-speed interposer 134 and the thermoelectric circuit layer 136.

To address challenges with placement accuracy the thermoelectric circuit layer 136 further comprises magnetic registers 144,146 and thermally conducting electrical insulating means 148 that envelopes the thru vias 138, the thermoelectric circuit(s) 140, and magnetic registers 144,146. FIG. 4B depicts the thermoelectric circuit layer 136 without its thermally conducting electrical insulating means 148 for the purpose of visual clarity.

The individual layers may be prefabricated before mounting them into the vertical stack assembly 102 or the vertical stack assembly 102 may be formed in situ. LCD processes taught by de Rochemont '839 are a preferred method of assembly because of its high deposition speeds (up to 25 μm/min), its ability to precisely control atomic composition with atomic scale uniformity of arbitrarily complex materials comprising an arbitrarily large number of distinct atomic elements, its ability synthesize glassy deposits, metals, alloys, superalloys, and electroceramics, ceramics, semiconductors in amorphous, single crystal, or polycrystalline phases with nanoscale microstructures. However, other methods that can replicate these capabilities may also be used under the scope of this invention.

To address challenges with placement accuracy, magnetic registers 144,146 comprising a magnetic material with sufficient coercivity to function as hard permanent magnetic materials to assist in placement accuracy. Neodymium-iron-boron NdFeB is a preferred material for making the magnetic registers 144,146 because of its high magnetic field strength. It is preferred to pattern the magnetic registers using photolithographic accuracy. Magnetic registers 144,146 are formed in all layers that have to be placed within a chip stack to improve placement accuracy when stacking prefabricated layers. North (South) magnetic poles are oriented to protrude from the top surface of the placed layer, with South (North) magnetic poles protruding from bottom of the placed layer. This allows magnetic coupling to snap the placed layers together through the magnetic force that attracts magnetic fields protruding from the top surface of a circuit layer located on a lower layer to attract oppositely polarized magnetic fields protruding from the bottom surface of the circuit layer mounted on its surface. x-y placement is assured by using corner magnetic registers 144. Side magnetic registers 146 are used to improve alignment in the theta orientation. Since lithographic means are used to pattern the locations and shapes of the magnetic registers 144,146 so there location relative to the vias has the accuracy of the lithographic process and offsets any errors in the placement of stacked components (die, interposers, thermoelectric circuits) caused by many mechanical inaccuracies. Hybrid bonding is used to stack prefabricated layers into the vertical stack assembly 102.

Preferred thermally conducting electrically insulating means 148 may comprise:
Aluminum Nitride which has thermal conductivity up to 220 Watts-m⁻¹K⁻¹ while providing excellent electrical insulation (>15 kV-mm⁻¹ breakdown voltages, low dielectric constant 8.5 at 1 MHz, high volume electrical resistivity ≥10¹³ Ω-cm.
Silicon Carbide and other MAX-phase ceramics which have thermal conductivity≈120 Watts-m⁻¹-K⁻¹ while providing volume electrical resistivity up to 10⁶ Ω-cm.
Aluminum Oxide which has thermal conductivity of 20 Watts-m⁻¹-K⁻¹ while providing volume resistivity in the range of 10¹⁴ to 10¹⁵ Ω-cm.

The selection of which thermally conducting electrically insulating means 148 to use is a design choice involving many factors, chiefly optimizing mechanical stability versus thermal energy transport through the high-speed semiconductor chip stack with active thermal management 100. Many methods are known to practitioners skilled in the art of semiconductor manufacturing to fabricate the thermally conducting electrically insulating means 148.

Advanced chemical mechanical polishing is applied to the top of each layer in the high-speed semiconductor chip stack with active thermal management 100 so each interfacial surface has a flat surface with average surface roughness R_{q}<0.5 nm. Surfaces of each circuit layer in the stack should be chemical mechanical polished to expose all top connecting elements, such as magnetic registers 144,146, through vias 138 and upper electrodes 152 between n-type 29A and p-type 29B thermoelectric bodies so maximal magnetic coupling efficiency, electrical signal continuity, and thermal contact is made with subsequent layers in the chip stack 100.

A second interposer layer 150, preferably a thinned interposer layer, is inserted between the thermoelectric circuit layer 136 and the thermal relief layer 154 to mate the electrical interconnections between the through vias in both layers 136,154. Thermal management is realized through the thermal relief layer 154 that comprises thermal shunts 104 that direct heat pulled from the heat generating semiconductor die 132 through the first and second high speed interposers 134,150 toward the bank of thermoelectric circuits 106 where a maximal percentage of the waste heat energy is converted into electrical power.

As depicted in FIGS. 4C and 4D waste heat energy generated by a first heat generating semiconductor die 156 is pulled through the vertical stack assembly 102 by thermoelectric circuits 106 and directed to the thermal relief layer 154 where it is transferred through a thermal shunt 104 comprising silver, or a metallic alloy or superalloy that has thermal conductivity in excess of 300 Watts-m⁻¹-K⁻¹. The metallic alloy or superalloy may contain silver, gold, nickel, platinum, aluminum or copper and have a composition that optimizes thermal conductivity, mechanical stability, and chemical robustness (bonding strength) in a vertical stacked assembly 106. Through vias 138 in thermal relief layers provide electrical continuity with circuitry located in other layers of the vertical stacked assembly 102. The through vias 138 are used in the thermal management of the vertical stacked assembly 102 and may comprise silver, or a metallic alloy or superalloy that has thermal conductivity in excess of 300 Watts-m⁻¹-K⁻¹ and may consist of silver, gold, nickel, platinum, aluminum or copper.

The thermal shunt 104 provides thermal communication to transfer heat from the thermal relief layer 154 to the bank of thermoelectric circuits 106 that serves dual functions as a heat sink (cold source to thermal relief layer) and a waste heat energy power conversion device. Insulating means 112, preferably amorphous silica, is used to concentrate the heat within the bank of thermoelectric circuits 106 and prevent it from leaking back into the high-speed semiconductor chip stack with active thermal management 100. Regulating thermoelectric circuits 122 are in thermal communication with the bank of thermoelectric circuits 106 through thermal heat sink trace 120 to complete the topology of the thermal management circuitry.

As illustrated in FIG. 4E, additional heat generating semiconductor die 158 may be added to the high-speed semiconductor chip stack with active thermal management 100 by mounting the additional heat-generating die 158 directly on thermal relief layer 154. Or, as may be required by a given design, an additional thermoelectric circuit layer 160 is inserted between the additional heat-generating die 158 and the thermal relief layer 154.

The vertical stacking process may be continued by sequentially repeating the process of mounting prefabricated or forming high-speed interposers 134,150, thermoelectric circuit layers 136,160 and thermal relief layers 154 progressively to the high-speed semiconductor chip stack with active thermal management 100 while mounting heat-generating semiconductor die 132,156,158 until a specific system objective is attained. It is preferred that with every thermal relief layer 154 that the thermal shunt 104 from that layer be in thermal communication with its own bank of thermoelectric circuits 106. This option allows for a more controllable active thermal management within the high-speed semiconductor chip stack 100 wherein each thermal relief layer 154 is thermally regulated by its own bank of thermoelectric circuits 106. As the high-speed semiconductor chip stack grows taller, the expanse of thermoelectric controls grows wider to occupy more real estate along the thermal heat sink trace 120.

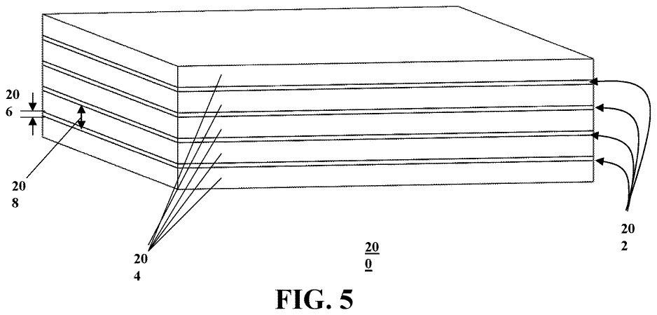

Reference is now made to FIG. 5 to illustrate means to provide mechanical stability to the high-speed semiconductor chip stack with active thermal management 100. Matching the coefficients of thermal expansion (CTE) between the various layers within the stack is essential to providing a stable mechanical structure. Mismatched CTEs between materials formed on an individual layer or between bonded layers can lead to tea-cupping deformations during thermal cycling where the mismatched layers bend towards the higher strength material with the lower CTE. High thermal conductivity materials for the thermal shunt 104 bodies that comprise silver, gold, nickel, platinum, aluminum or copper typically have high coefficients of thermal expansion ranging from 13×10⁻⁶/°C to 25×10⁻⁶/°C which conflicts with 0.5×10⁻⁶/°C for amorphous silica (used as insulating means 112) and 2.6×10⁻⁶/°C for silicon often used as heat generating semiconductor die 132,156,158. (See Table I).

TABLE I
Coefficients of Thermal Expansion

| High Thermal Conductivity Metals | | Nearby Components in Stack | |
|---|---|---|---|
| Silver | 18 × 10⁻⁶ / °C | α-Silica | 0.5 × 10⁻⁶ / °C |
| Gold | 14 × 10⁻⁶ / °C | | |
| Nickel | 13 × 10⁻⁶ / °C | Silicon | 2.6 × 10⁻⁶ / °C |
| Aluminum | 25 × 10⁻⁶ / °C | | |
| Copper | 17 × 10⁻⁶ / °C | | |

The high thermal conductivity metals are typically malleable and can withstand a lot of internal stress without fracturing. Therefore, it is desirable to embed constraining members 202 that comprise high-strength materials with low coefficients of thermal expansion between thermally conductive members 204 within a thermal shunt 104 body to form a modified thermal shunt 200 that has an effective CTE that is more closely matched with neighboring components and thus greatly reduces the mechanical strain applied within the high-speed chip stack with active thermal management 100. Constraining metal members 204 may comprise, but are not limited to, kovar, invar, aluminum nitride and molybdenum or chemically complex MAX-phase ceramics with CTE values in the range of 0.72×10⁻⁶ °C to 9.4×10⁻⁶ °C. (See Table II). The constraining member thickness ideal thickness 206 is preferably 5% of the thermally conductive member thickness 208. The objective is to engineer the modified thermal shunt 200 so it endows the high-speed semiconductor chip stack 100 with maximal mechanical stability. More than one type of constraining member 202 may be used to achieve this objective to optimize the desired properties of the modified thermal shunt 200.

TABLE II
Properties of Constraining Members

| Constraining | Hardness | Thermal Conductivity | Coefficient of |
|---|---|---|---|
| Member Body | (GPa) | (Watts-K⁻¹-m⁻¹) | Thermal Expansion |
| Invar | 1.57 | 12.8 | 1.2-2.0 × 10⁻⁶ / °C |
| Super Invar | 2.5 | 8.0 | 0.72 × 10⁻⁶ / °C |
| Kovar | 1.18 | 17 | 4.9 × 10⁻⁶ / °C |
| Molybdenum | 1.4-2.7 | 139 | 4.9 × 10⁻⁶ / °C |
| AIN | 11-13 | 170 | 4.15 × 10⁻⁶ / °C |
| MAX-Phase | 14-20 | 12-60 | 6.3-9.4 × 10⁻⁶ / °C |
| Ceramic | | | |

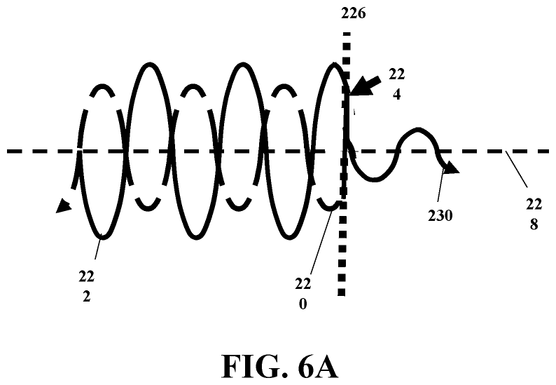

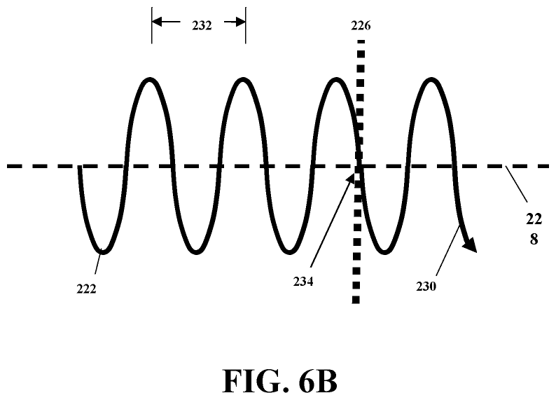

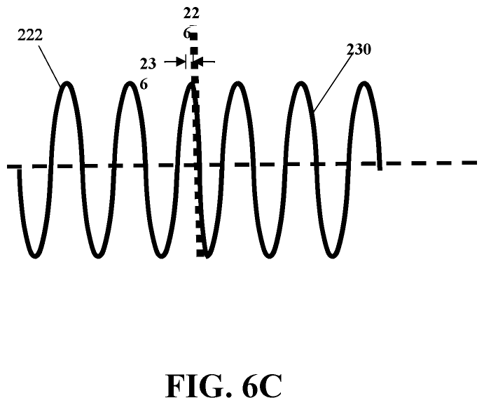

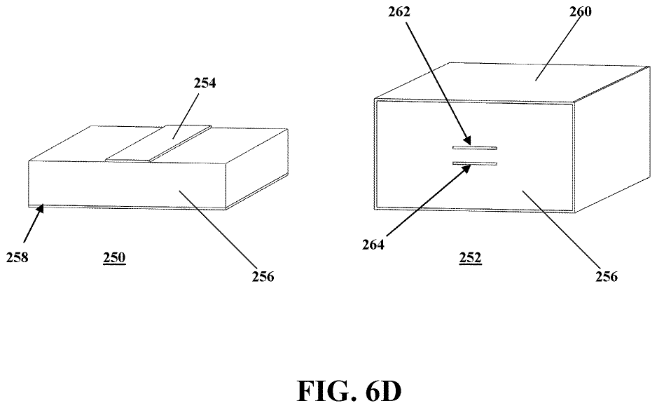

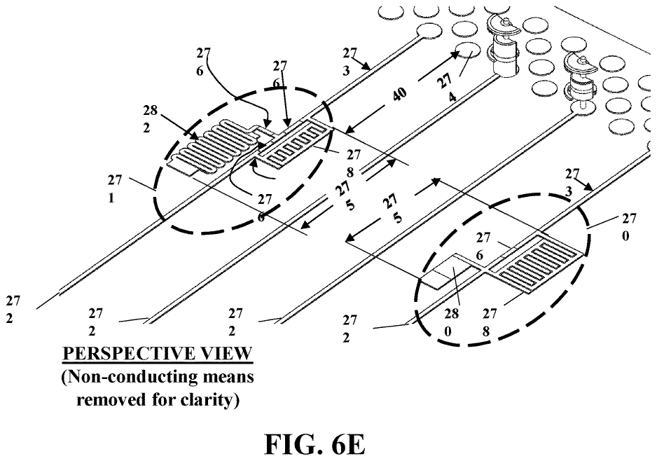

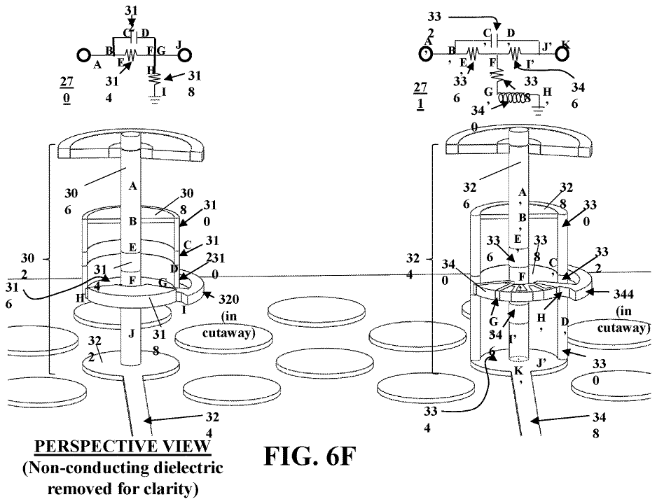

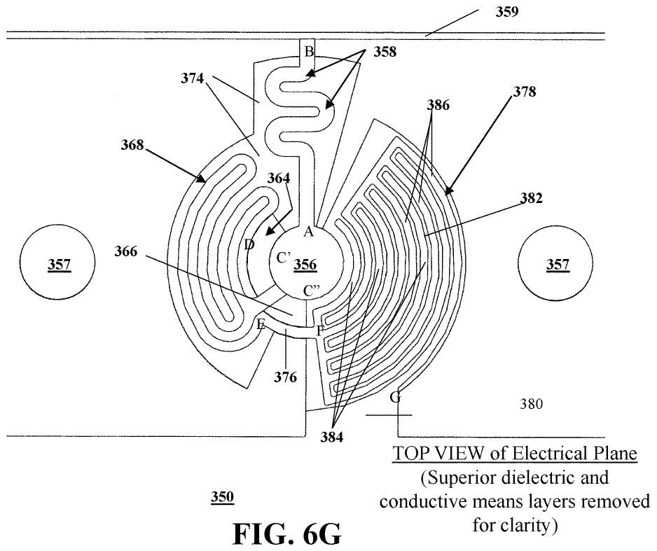

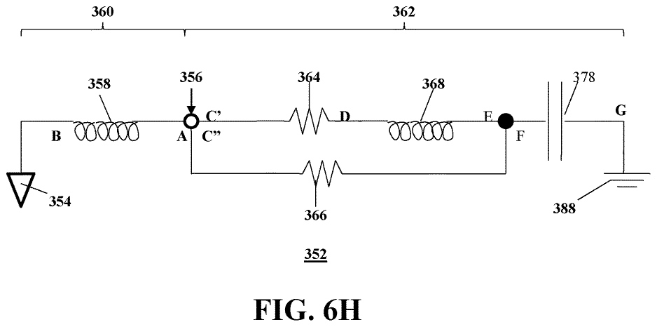

Reference is now made to FIGS. 6A, 6B, 6C to illustrate means to improve signal integrity in a high-speed semiconductor chip stack with active thermal management 100. Signals are reflected at discontinuities in the transmission line where the signal path changes directions. This directional change can in the plane of layer or a connection to another layer in the stacked assembly. As illustrated in FIG. 6A, signal reflections 220 occur when the amplitude of the electromagnetic wave carrying the signal's electric field of the incident signal wave 222 is non-zero 224 when crossing the plane of the discontinuity 226 along the signal path 228. The transmitted signal 230 moves through the discontinuity with its electric field amplitude reduced in strength by the amplitude of the reflected wave 220. The reflected wave 220 destructively interferes with the electric field of the incident electromagnetic wave 222 and causes ringing in the circuit which disrupts the integrity of the signal being communicated through the circuit.

As illustrated in FIG. 6B, no signal power is lost due to reflections when the signal crosses the plane of discontinuity 226 when the transmission lines are properly terminated. One method to properly terminate a transmission line is to construct the signal path 228 length such that it is exactly an integer multiple of the wavelength 232 of the standing wave between the signal source or the last plane of discontinuity from which it currently originates. When the electric field amplitude of the standing wave for the incident carrier signal is zero 234 exactly at the plane of discontinuity 226. there is no reflected signal and the full power of the incident wave 222 passes through the plane of discontinuity 226 in the transmitted signal 230. In tight confined volumes like a stacked assembly 102, which are prone to having a lot of signal path discontinuities there is not always the space along the signal path to accommodate a path length between discontinuities that is a multiple integer of the carrier signal wavelength.

Passive components adjust the phase velocity of signals traveling along a transmission line and can be used to terminate signals at the plane of discontinuity by making a phase velocity adjustment 236 through the plane of discontinuity 226 to preserve signal integrity as shown in FIG. 6C. This impedance matching filter allows the full power of the incident wave 222 to be passed through the discontinuity 226 to the transmitted signal 230.

Therefore, it is a preferred embodiment of this application that the high-speed semiconductor chip stack with active thermal management 100 additionally comprise impedance matching components that comprise capacitive elements that consist of electroceramic dielectric having a uniform nanoscale microstructure wherein all grains 21 have identical grain core chemistries and uniform diameter 23. This attribute will quench ion transport mechanisms within the electroceramic dielectric that causes its physical properties to vary with temperature, frequency, applied voltage bias and time (aging). It is a further preferred embodiment of this application that grain boundaries 25 within capacitive elements additionally comprise highly insulating amorphous silica to block leakage currents 27 that would otherwise flow through conductive oxides that migrated into the grain boundaries 25 though impurities in the deposited solid solution (glass) as it is annealed into a polycrystalline dielectric element.

Maximal signal integrity can be achieved by embedding capacitive elements comprising high-κ dielectric, ε_{R}≥200, with uniform nanoscale microstructure and inductive elements comprising magnetic cores having permeability μ_{R}≥25 as impedance matching devices. In general, impedance matching devices with higher intrinsic performance values (ε_{R}, μ_{R}) require more chemically complex and can comprise 7-9 distinct atomic elements. This makes liquid chemical deposition (LCD) a preferred manufacturing method because of its ability to produce deposits with atomic scale chemical uniformity and compositional precision at high deposition rates (up to 25 μm-min⁻⁴). To achieve maximal signal integrity the intrinsic performance values must remain constant with varying operational conditions (changing temperature, applied voltage, signal frequency and time (aging)). In capacitive dielectrics nanoscale microstructures will endow the components with stable performance over operational temperatures, applied voltages, signal frequencies and time. In fact, capacitive dielectrics fully polarize in microseconds to tenths of a nanosecond if they contain electroceramic grains >50 nm, whereas a dielectric body with nanoscale microstructure will fully polarize on femtosecond timescales because the polarization process is limited to orbital deformations (a quantum process). Ion transport mechanisms contribute to the polarization by expanding or contracting the unit cells within the electroceramic grains. The physical deformation process of the crystalline structure eventually degrades performance over time (aging), therefore it is a preferred embodiment of this application to utilize electroceramics with nanoscale microstructures to ensure stable performance values in all operating conditions and over signal frequencies that approach the peta-hertz (PHz) domain.

Silica garnets are preferred for magnetic cores operating at higher signaling frequencies but limited stability in performance is only achievable in highly complex compositions that have compositional precision, which makes LCD a preferred method to construct these components.

Signal integrity is also affected by transmission lines 250,252 depicted in FIG. 6D. The transmission line structure comprises conductive means 254, a non-conductive dielectric body 256 and a conductive ground plane 258. The preferred transmission line embodiment for the high-speed chip stack semiconductor chip stack with active thermal management 100 comprises a ground-cladding 260 enveloping a non-conductive dielectric body 256, further comprising a first conductive means 262 that carries the signal and a second conductive means 264 that carries the return signal 264, where both conductive elements (262,264) are located in the center of the non-conductive dielectric body 256. The conductive means 254,262,264 may comprise a metallic element, a metal alloy, a metallic superalloy, or a ceramic, wherein the metallic element, metal alloy or metallic superalloy might further comprise silver, gold, nickel, platinum, aluminum or copper and the ceramic conductive means might comprise a ceramic superconductor. The ground cladding 260 provides maximal isolation from crosstalk interference originating from nearby transmission lines that are adjacent to the signal carrying transmission line to minimize jitter that adversely impacts signal integrity.

Amorphous silica, which has a loss tangent (tan δ) in the range of 10-4-10 and a stable dielectric constant ε_{R}μ_{R} with minimal dispersion over frequencies up to near-infrared electromagnetic spectrum, is the preferred embodiment for non-conductive means 254. High complexity glasses that exhibit low loss and minimal dispersion characteristics may also be deployed as the non-conductive means 254.

With stable low-loss transmission lines, impedance matching circuitry may now located within that I/O channels, the vias, or the via pads using extreme chemical complexity dielectric bodies that enable a maximal degree of component miniaturization. FIG. 6E illustrates means to embed anti-distortive filtering circuits 270 and 271 within the I/O channel 272. The stubs 273 electrically connect the anti-distortive filtering circuits 270.271 to a via pad 274 and preferably have stub lengths that are less than 50 μm. The anti-distortive filtering circuits 270,271 are designed to have physical dimension 275 that is less than λₒₚ/20, where λₒₚ is the wavelength of operating signal frequency (clock speed) in the high-speed. semiconductor chip stack with active thermal management 100. The anti-distortive filtering circuits 270,271 may comprise resistive elements 276, inter-digitated capacitive elements 278, single layer or multilayer planar capacitive elements 280, and inductive elements 282.

Anti-distortive filtering circuits 270,271 may also be embedded with vias as shown in FIG. 6F, where the example circuit diagram is shown above each illustration of the passive anti-distortive filtering circuit embedded within the via structure. In this preferred embodiment of the high-speed semiconductor chip stack with active thermal management 100, the stub length 40 is effectively eliminated.

FIG. 6F illustrates an embedded passive equalizer 300 and/or termination circuitry vertically across multiple planes within a via structure 11 through an interposer 134,150. A vertically integrated passive equalizer embedded within a via 302 effectively has zero stub length 40 because all passive circuitry is located directly beneath the pin of a device and all elements of the vertically integrated passive equalizer embedded within a via 302 have physical dimension that fall within the “lumped circuit” limit. A vertically integrated passive equalizer embedded within a via 302 having MAXIM topology may comprise a micro via shaft 306 that serves as the network filter's input at point A. The input signal encounters a circuit branch at point B, where part of the signal is directed through a via pad 308 to a cylindrical conductor 310 formed around the micro via shaft 306 to point C, which is the input to a planar capacitive element 312 configured around the micro via shaft 306. The planar capacitive element 312 has its output at point D.

A second branch of the vertically integrated passive equalizer embedded within a via 302 having MAXIM topology carries another portion of the signal from point B to point E through the micro via shaft 306, which is the input to a first planar resistive element 314 formed within the micro via shaft 306 that outputs the signal at topological circuit point F.

The signal outputs from points D and F conjoin at point G, which is a via pad 316 for which a portion comprises a second planar resistive element 318 having its input at point H that, in turn, makes electrical contact to conductive means 320 forming a ground plane (illustrated in cutaway for clarity) at point I. The vertically integrated passive equalizer embedded within a via 302 having MAXIM topology has its output at point J, which is in electrical communication with a via pad 322 in electrical contact with the I/O channel link of the high-peak bandwidth I/O channel.

Similarly, vertically integrated passive equalizer embedded within a via 324 having AGILENT topology may comprise a micro via shaft 326 that serves as the network filter's input at point A′. The input signal encounters a circuit branch at point B′, where part of the signal is directed through a via input pad 328 to a cylindrical conductor 330 formed around the micro via shaft 326 to point C′, which is the input to a planar capacitive element 332 configured around the micro via shaft 326. The planar capacitive element 328 has its output at point D′. A cylindrical conductor 330 provides electrical communication with a via output pad 334 that serves as point J′ in the embedded filtering circuit 271.

A second branch of the vertically integrated passive equalizer embedded within a via pad 324 having AGILENT topology carries another portion of the signal from point B′ to point E′ through the micro via shaft 326, which is the input to a first planar resistive element 336 formed within the micro via shaft 326 that outputs the signal at point F′. Point F′ branches another part of the signal through a second planar resistive element 338 that is configured in arcuate fashion around micro via shaft 326 and is connected in series to a planar inductive element 340 that is also configured in arcuate fashion around micro via shaft 326 and terminates at point G′ where it electrically connects to conductive means 342 forming a ground plane contact 344 (illustrated in cutaway for clarity) at point H′.

The micro via shaft 326 of vertically integrated passive equalizer embedded within a via 324 having AGILENT topology carries a portion of the signal from point F′ through third planar resistor 346 embedded within micro via shaft 326. The third planar resistor 346 has its output at point J which electrically connects to via output pad 334.

Branched signals from points D′ and I′ in the vertically integrated passive equalizer embedded within a via 324 having AGILENT topology conjoin at point J′ where via output pad 334 electrically connects the branched signal in the micro via shaft 326 with the branched signal in cylindrical conductor 330 to the I/O channel link 348 of the high-peak bandwidth I/O channel at point K′ to complete the circuit and equalize the I/O channel with passive electroceramic dielectric that remains stable with all operating factors.

Another preferred embodiment of the application shown in FIGS. 6G,6H uses the high energy density chemically complex electroceramics to integrate passive network filters within a via pad wherein some of electroceramic dielectric has nanoscale microstructure 29. The integrated via pad 350 uses high-κ dielectric electroceramics to form the passive filtering network 352 illustrated in FIG. 6H. Any variety of passive filtering network may incorporated within the integrated via pd 350 for the purpose of impedance matching, equalizing or anti-distortive purpose that otherwise improve signal integrity in the high=speed chip stack with active thermal management 100. The passive filtering network 352 is merely used to describe how passive filtering circuitry is integrated within an integrated via pad 350. The passive filtering network 352 depicted in FIG. 6H comprises a driven device 354 that is electrically supplied by currents emanating from via pad 356 located at point A and subsequently flowing through a first inductor 358 before being electrically connected to device 354 at topological circuit point B. A conducting trace 359, which may be in electrical communication with the device 354 through other via pads 357 comprising integrated vias 350 electrically connects the passive network filter 352 to the driven device 354. The via pad 356, which are adjacent to other via pads 357 that may electrical connect to integrated passive circuitry on other circuit layers within an interposer 104. The first branch of the passive network filter 360 maintains electrical communication with a second branch 362 through via pad 356 at topological points C′,C″. The second branch of the passive network filter 362 forms an electrical connection to a first resistor 364 configured in parallel with a second resistor 366. The first resistor 364 is configured in series with a second inductor 368 at topological point D. The second resistor 366 completes its parallel connection with the first resistor 364 at topological point F, which also is in electrical communication with the second inductor 368 through topological point E. Topological points E,F are in electrical communication with the input leads of a capacitor 370, which has its output leads in electrical communication with a grounded conductor 372 at topological circuit point G to complete the passive filtering network 350.

In addition to making direct electrical connection to conducting trace 359 through a first inductor 358 embedded within a chemically complex magnetic core 374 that has μ_{R}≥25 where the conducting trance 359 is in electrical communication with a driven device 354, the integrated via pad 350 electrically connects at topological point C′ to a ceramic first resistor 364 that is in electrical communication through an arcuate serpentine conductive coil embedded with the chemically complex magnetic core 371 to forms the second inductor 368. The chemically complex magnetic core 374 material has electrically resistivity >10⁸ Ω-cm. The output of the second inductor 368 joins conductive element 376 at topological point E where a parallel electrical connection is made to integrated via pad 356 at topological point C″ through a second resistor 366. Conductive element 376 makes serial connection at topological circuit point F to the input of an inter-digitated capacitor 378 that as its output in electrical communication with grounded metallization 380 to complete the passive filtering network 350 at topological circuit point G. High-κ electroceramic dielectric with nanoscale microstructure 382 is inserted between the input digits 384 and the output digits 386 of the inter-digitated capacitor 378. The output of the inter-digitated capacitor 378 is in electrical communication with a grounded electrode 388 at topological point G. Inter-digitated capacitor 378 is an arcuate structure circumferentially formed around integrated via pad 356.

Thermal throttling is a self-preservation measure that prioritizes component safety over performance on heat-generating semiconductor die, like central processing units (CPUs) and graphics processing units (GPUs). CPUs are the primary computational component in hardware that executes instructions through an instruction cycle from software and hardware. They remain foundational to computing balancing speed, power consumption, and parallel processing by performing arithmetic, logic, and control operations enabling devices to run operating systems and applications. GPUs are a specialized electronic circuit designed to accelerate the creation and rendering of images, videos, and animations by performing rapid mathematical calculations. Initially developed for handling 2D and 3D graphics in gaming and professional applications, modern GPUs have evolved to support parallel processing for a wide range of tasks, including AI, machine learning, video editing, and scientific simulations.

CPUs and GPUs generate heat that is nearly equivalent to their power consumption, 99.9% for CPUs and over 99% for GPUs through resistive heating and the switching of billions of transistors. These heat-generating die 158 consume over 350 Watts. of power each and comprise thermal sensors that reduce clock speeds and lower voltage to avoid damaging these components. So even if the high-speed semiconductor chip stack has been engineered for high signal integrity at higher frequency, the heat-generating die 158 are designed to lower operational clock speeds as they heat up. So, few gains are realized unless the generated heat issue is addressed. Therefore, high-speed semiconductor chip stacks with active thermal management constitutes a major development in microelectronics that has great commercial value.

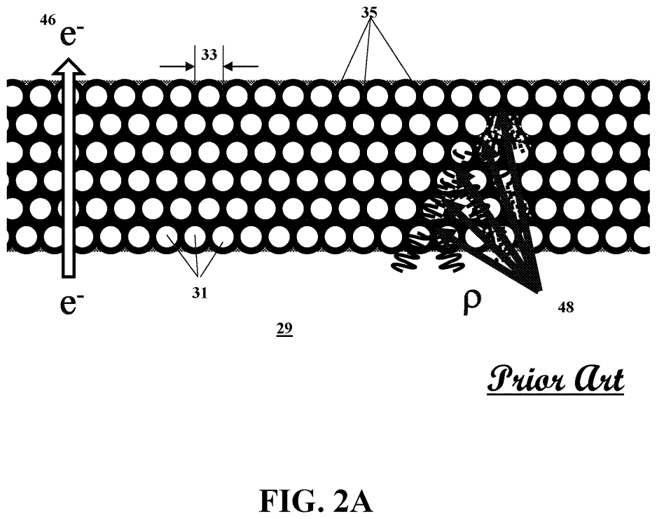

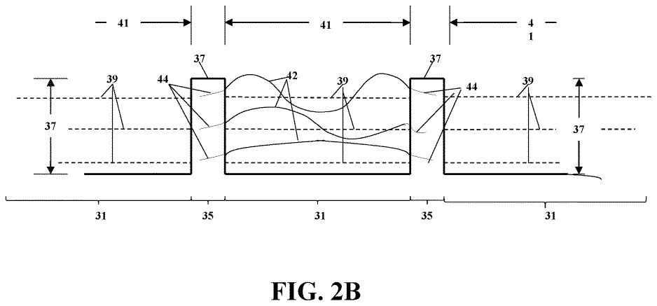

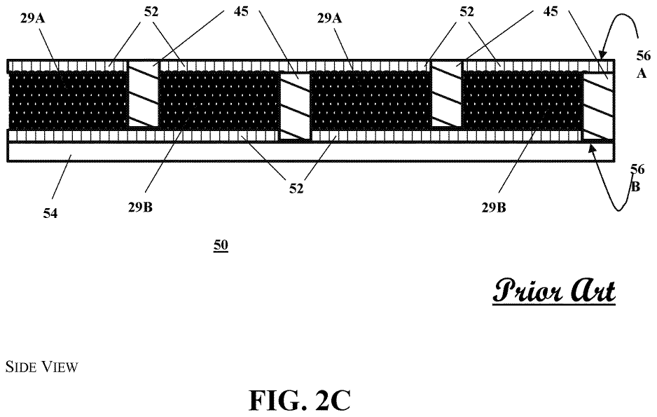

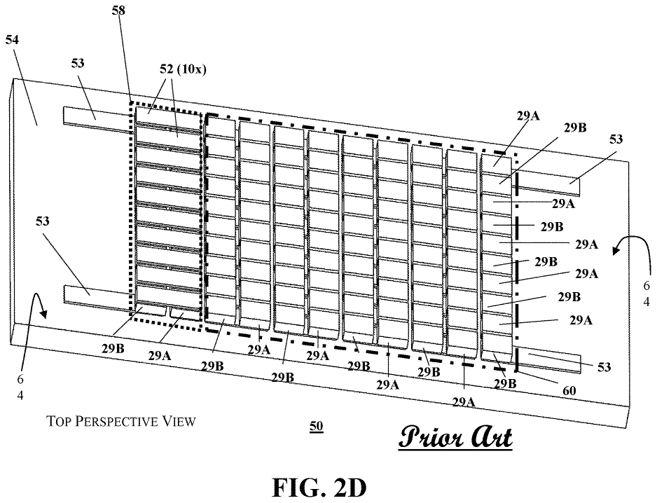

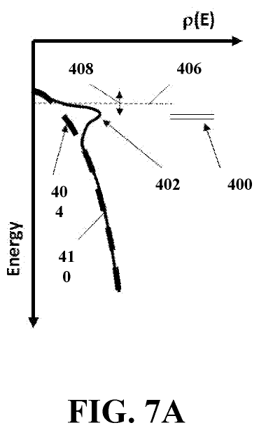

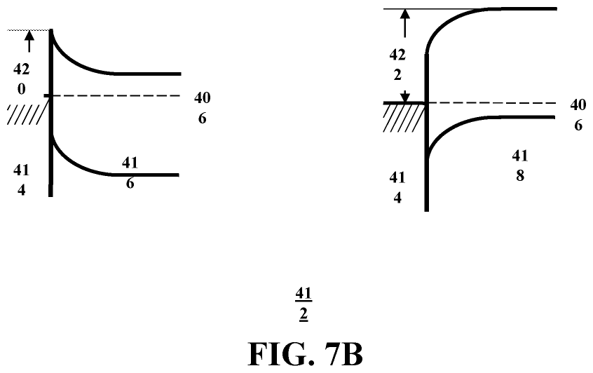

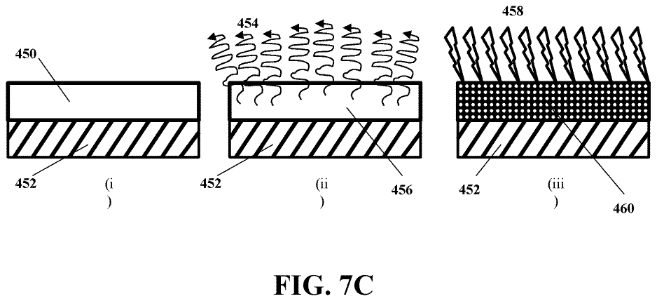

Reference is now made to FIGS. 7A, to illustrate means to minimize thermal throttling in vertical chip stack assemblies 102. Thermoelectric bodies 29 comprising nanoscale microstructure is essential to this solution as shown in FIG. 2A. Two instances of thermoelectric bodies 29 are preferred embodiments for this application. The first instance comprises nanoscale semiconductor grains 31 having grain size 33 less than or equal to 50 nm without a distinct grain boundary material 35 that interconnects the grains. In this instance, crystalline lattice defects cause the heat carrying phonons to strongly scatter 48 (be reflected) at the boundaries between the grains. Any polycrystalline semiconductor with nanoscale microstructure could be applied in this application, however semiconductors from the Skutterudite family of semiconductors are preferred for their high thermoelectric figures of merit (zT), ranging between 1.7 to 1.9 even without nanoscale microstructures.

The Skutterudite family of thermoelectric semiconductors has thermal conductivities generally in the range of 1.6-1.9 W-m⁻¹-K⁻¹ and conform with the general chemical formula

AB₃ (3)
where A is a metal atom or fractional combination of transitional metal group elements, preferably from the group consisting of, but not limited to: A=Ru, Pa, Fe, Co, Ir, Rh, Ni, Os, Pt,
and,
B is a non-metal or semi-metallic atom or a fractional combination of pnictogen group elements, preferably from the group consisting of, but not limited to: B=Bi, Sb, Te, Pb, Ge, Se, S, As, Si.

In general, thermal conductivity is lower in materials that have weaker interatomic bonding energies (weaker bonds) formed between elements having higher mass, therefore it is advantageous to incorporate materials that comprise elements having a higher atomic mass. The Skutterudite family of semiconductors can be chemically modified by adding alkali elements to further reduce thermal conductivity according to the formulas:

Z₂A₈B₁₃ (4)
where A is a metal atom or fractional combination of transitional metal group elements, preferably from the group consisting of, but not limited to: A=Ru, Pa, Fe, Co, Ir, Rh, Ni, Os, Pt,
B is a non-metal or semi-metallic atom or a fractional combination of pnictogen group elements, preferably from the group consisting of, but not limited to: B=Bi, Sb, Te, Ge, Se, S, As, Si,
and,
Z is an alkali metal atom or fractional combination of alkali metal element, preferably consisting of the heavier atomic mass element: K, Rb, Cs.

The higher figures of merit (zT) for the Skutterudite families of semiconductor are evident through their low thermal conductivities and the relationships defined by equations (1) and (2). Nanoscale microstructures strengthen phonon scattering to lower thermal conductivity further while the quantized electron (hole) states within the grain cores 31 increase the electron/hole mobilities (μ_{electron}/μₕₒₗₑ) in the tunneling currents 46, which impacts electrical conductivity through the energy-dependent electrical conductivity σ(E) expressed as:

σ(E)=n(E)·q·μ(E) (5a)

n(E)=ρ(E)·ƒ(E) (5b)
where
   n(E) is the charge carrier density
   q is electric charge of an electron (hole)
   μ(E) is the energy-dependent charge carrier mobility.
ρ(E) is the energy-dependent density of states
ƒ(E) is the Fermi function.

Using these descriptive parameters the Seebeck coefficient, S, can be expressed in terms of the logarithmic derivative of the energy-dependent conductivity σ(E), which correlates to:

$$S = \frac{{π}^{2} {k}_{B}^{2} {S}^{2}}{3 q} \{ \frac{d [ ln ( σ ( E ) ) ]}{dE} \} {\vert}_{E = {E}_{f}} \qquad ( 6 a )$$

$$= \frac{{π}^{2} {k}_{B}^{2} T}{3 q} \{ \frac{1}{n} \frac{d n ( E )}{dE} + \frac{1}{μ} \frac{d μ ( E )}{dE} \} {\vert}_{E = {E}_{f}} \qquad ( 6 b )$$

Using the expression given in equation 6b, the two mechanisms through which the Seebeck coefficient, S, can be enhanced by means of materials design and engineering is by introducing a solid-state structure that sharply increases the energy-dependence of the mobility, μ(E), of the conducting charge carriers, or by sharply increasing the energy-dependence of the charge carrier density, n(E).

A larger energy dependence in n(E) can be achieved (through equation 5b) by introducing quantized sub-bands 400 that produce a strong distortion 402 in the normal charge carrier density of states profile 404 ρ(E) at energy-levels that closely align with the material's Fermi energy 406, E_{F}, as shown in FIG. 7A. To enhance thermopower, the distortion 402 must lie within a small range ER 408 of the semiconductor's Fermi-level E_{F} 406. Consequently, the composition of the semiconductor with nanoscale microstructure 460 must induce quantized sub-bands 400 that modify the density of states 410 such that the quantized sub-bands 400 are energetically located in the conduction band of an undiluted n-type semiconductor material, or induce sub-bands 400 that resonate (align) with the valence band of an undiluted p-type semiconductor material.

The second instance of thermoelectric bodies 28 comprise a nanoscale microstructure with a semiconductor grain core 31 and a distinct grain boundary material 35 that induces an electrical junction that creates a potential barrier 37 between at the interface between the semiconductor grain core 31 and the distinct grain boundary material 35. In this instance the semiconductor grain core 31 material preferably comprises a group IV semiconducting element selected from the elemental group consisting of carbon (C), silicon (Si), germanium (Ge), tin (Sn), or lead (Pb), or a IV-IV semiconducting alloy comprising two or more elements selected from the elemental group consisting of carbon (C), silicon (Si), germanium (Ge), tin (Sn), or lead (Pb), and the distinct grain boundary material 35 comprises a metal or metallic alloy consisting of:
an alkali metal (lithium (Li), sodium (Na), potassium (K), rubidium (Rb), cesium (Cs), or Francium (Fr)) or admixture thereof, or
an alkaline earth metal (beryllium (Be), magnesium (Mg), calcium (Ca), strontium (Sr), barium (Ba) or an admixture thereof, or
an alloy or superalloy of alkali earth metals and alkaline earth metals.

The potential barrier formed between the group IV semiconductor or group IV-IV semiconducting alloy within the grain core 31 and the alkali/alkaline earth metal used as the distinct metal grain boundary 35 is a Schottky junction. Schottky junctions 412 are formed between a metal 414 and n-type 416 or p-type 418 semiconductors are as shown in FIG. 7B. The potential energy barrier 420, φ_{Bn}, between a metal 414 and n-type 416 semiconductor is given by equation 7a and the potential energy barrier 422 between a metal and p-type semiconductor is given by equation 7b.

qφ_{Bn}=q(φ_{M}−χ) (7a)

qφ_{Bp}=E_{gap}−q(φ_{M}−χ) (7b)

where φ_{M} is the metal work function, χ is the semiconductor electron affinity, q is the electron charge, and E_{gap} is the semiconductor band gap. The work function φₘ of a given metal composition can be measured through the Photoelectric Effect, using Photoemission Spectroscopy (PES); Thermionic Emission; or Field Emission. Semiconductor Electron Affinity χ is measured by Inverse Photoelectron Spectroscopy (IPES) or Low-Energy Inverse-Photoemission Spectroscopy, which is a refined version of IPES. Semiconductor band gaps are measured using optical methods (direct band gap, Boltzmann Function Fitting that use the measured absorption) to determine E_{gap}, or electrical methods, such as Four-Probe Resistivity, which measures resistivity versus temperature to determine activation energy, or Photoconductivity that monitors conductivity changes under varying photon energy where the onset of the photocurrent corresponds to E_{gap}.

LCD methods (illustrated in FIG. 7C) are a preferred method to fabricate of thermoelectric bodies 28 for its economic efficiencies and ability to form amorphous bodies with atomic scale chemical uniformity and materials with nanoscale microstructure. LCD methodology initially forms an initial deposit 450 as a sprayed solid-solution (glassy/amorphous) on a substrate 452 (i) at substrate temperatures low enough not to damage transistor dopant profiles, so the deposited materials can integrate passive filtering networks having nanoscale microstructure with active circuitry on the same substrate. The initial deposit 450 has organic residual material from incomplete deflagration of liquid metalorganic precursors. A Bake-out Step (ii) is used to remove excess organic residuals 454 from the initial to prepare a clean deposit 456 without the potential to form undesirable carbonate phases during processing. Finally, a plasma annealing step 458 (iii) is applied to convert the glassy amorphous clean deposit 456 into a polycrystalline or fully crystalline deposit. A deposit with nanoscale microstructure 460 evolves using a 500 W power plasma annealing step 458 for 10-90 seconds.

High thermopower (zT) thermoelectric bodies 28 are achieved by maximally aligning the Fermi-level 406 with the strong distortion 402 in the normal charge carrier density of states profile 404 ρ(E) caused by the quantized sub-bands 400. High chemical complexity with atomic scale chemical uniformity is a requirement to achieve optimal alignments. Material composition determines Fermi-levels E_{F}, metal work function φ_{M}, semiconductor electron affinity χ, and semiconductor band gaps E_{gap} that are parameters used to determine maximal alignment (resonance) of the sub-bands 400.

Fermi-levels, E_{F}, are determined by the intrinsic purity and level of n-type and p-type doping in the semiconductor material. Substituting boron (B) and aluminum (Al) for the Group IV, IV-IV elements in those semiconductors will dope them for p-type electronic behavior, while substitutions made with phosphorous (P), arsenic (As), or antimony (Sb) will produce n-type behavior. Similar valence band considerations are used to dope group IV-VI semiconductors.

Electronic energy band gap, E_{gap}, and electron affinity, χ, are determined by the elemental composition of the semiconductor. Therefore, the ability to easily produce highly complex Group IV-IV and Group IV-VI semiconductors facilitates a high degree of E_{gap} and χ energetic tuning.

Similar tuning is possible for tuning the metal work functions φ_{M}. Instead of making 3D quantum wells with an alkali metal or an alkali Earth metal as the enveloping distinct grain boundary material as previously taught in de Rochemont '302 and de Rochemont '768, it is a preferred embodiment of this application that the distinct grain boundary material 35 enveloping the semiconductor grain core 31 further comprise an alloy or superalloy consisting of a plurality of alkali or alkaline Earth elements to achieve more precise tuning of the distinct grain boundary material's 35 work function φ_{M}. Alkaline Earth metal have a larger variance in their work function potentials and are used for making gross adjustments to the potential barrier φ_{M}, whereas as alkali metals have distinct but minor changes and are used for making fine adjustments to the potential barrier φ_{M}.

The atomic scale chemical uniformity in the amorphous initial deposit 450 is preserved during the bake-out step that removes the organic residuals 454. The liquid precursors used in LCD mix the various metalorganic precursors at the molecular level. This level of subdivision is preserved during the deposition process (i) and the bake-out step (ii) so the clean deposit 456 comprises an amorphous inorganic body with atomic scale chemical uniformity and precise elemental composition. When the precise composition of the clean deposit 456 consists of a majority compositional fraction with molar ratios sufficient to form a nanoscale volume with the stoichiometry of a doped IV, IV-IV, or IV-VI semiconducting grain core 31, and a minority compositional fraction consisting of the molar ratios to form the desired potential barriers φ_{M} at the grain boundaries, the plasma-activated crystal nucleation fields will form the desired grain cores 31 during the plasma annealing 458 step (iii) and will push the thermodynamically incompatible atoms from Group I (alkali metal) and Group II (alkaline Earth metal) elements out of the crystallizing grains to collect at the grain boundaries to form distinct boundary materials 35 matching the residual composition in the minority compositional fraction remaining in the clean deposit 456.

Similar methods disclosed in de Rochemont '302 teach methods to form 3D quantum wells with Group II-VI semiconductor grain cores 31 enveloped by Group IV or Group IV-IV semiconducting distinct grain boundary material 35, or to form Group III-V semiconductor grain cores 31 enveloped by Group I-VII insulator distinct grain boundary material 35. Thermoelectric bodies 28 might additionally comprise these combinations of grain core/grain boundary materials depending up the design requirements for a given application as a preferred embodiment.

The above mentioned embodiments provide sufficient thermopower to cool heat generating die semiconductor 158 within a high-speed chip stack with active thermal management 100 to mitigate thermal throttling.

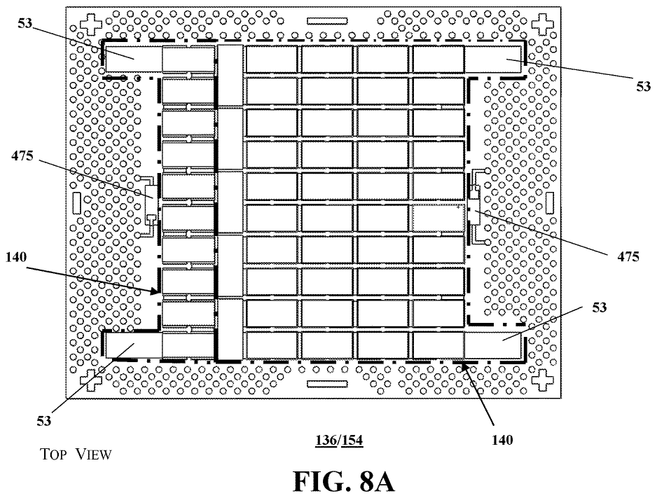

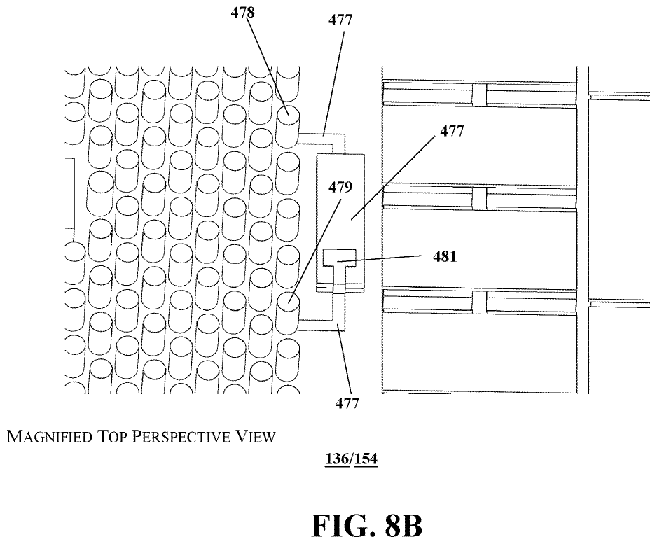

Reference is now made to FIGS. 8A,8B to illustrate how thermoelectric circuit layers 136 regulate temperature in high-speed chip stacks with active thermal management 100. Local temperature is regulated by forming thermocouple sensors 475 within the thermal relief layers 136,154 that preferably that measure the temperature for each thermoelectric circuit 140. Conductive traces 477 electrically connect each thermocouple sensor to a through via that is in electrical communication with a ground plane 478. Signal pins 479 place the thermocouple output pad 481 in electric communication with through vias that lead to a thermal control chip 483 in the high speed chip stack with active thermal management 100. The thermal control chip 483 compares the voltage received through the signal pins 479 to a reference or programmable set point voltage. It then modulates the current being supplied to the input/output electrodes 53 to the thermoelectric circuit(s) 140 to keep the high-speed semiconductor chip stack with active thermal management 100 at an optimal temperature to maximize processor clock speeds and minimize thermal throttling.

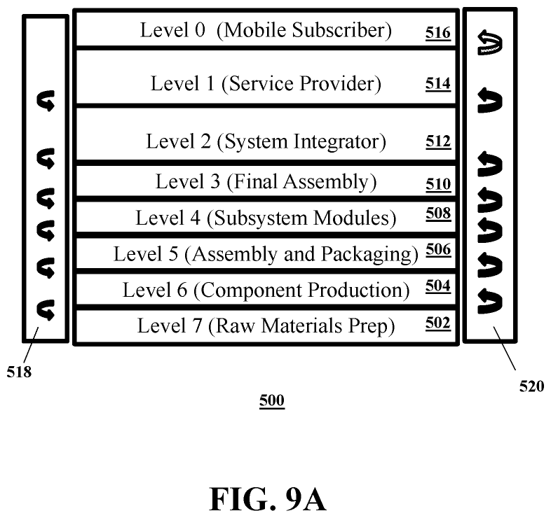

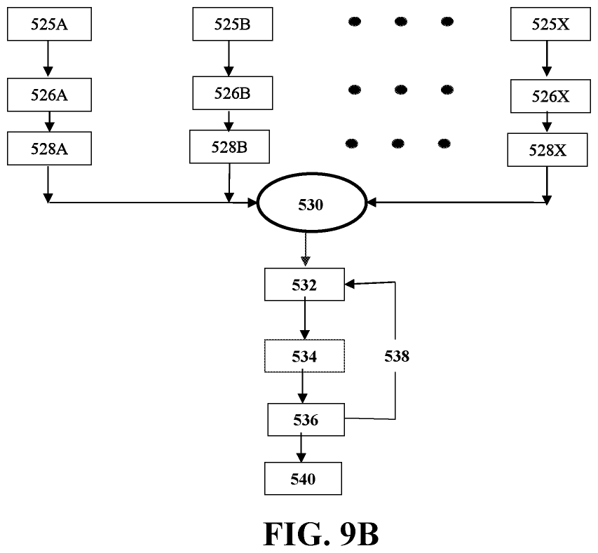

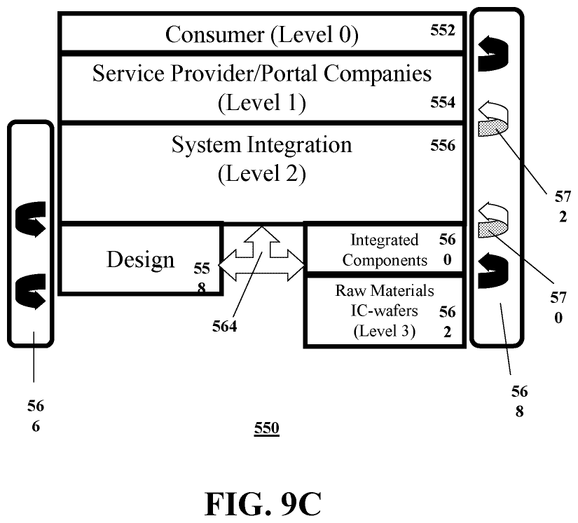

Reference is now made to FIGS. 9A, 9B to illustrate how the ability to integrate passive circuit elements comprising nanoscale microstructure and compositional uniformity with precise (0.0% variance) compositional controls over large surface areas and run-to-run accuracy reduces the microelectronic supply chain into a streamlined production system with minimal logistical dependencies to address cost implications associated with semiconductor chip stacks. FIG. 9A illustrates the complex legacy supply chain 500 for mobile wireless devices that are now the primary End-User device 618 used to interact with global IT systems 602. The discrete assembly of passive components on printed circuit boards is the greatest cause of the complexity of the microelectronic supply chain 500. The discrete assembly of large numbers of tiny, low value parts adds large costs that manifest as Cost-of-Goods-Sold (COGS) charges that account for repair, assembly and test, procurement and sourcing, inventory and logistic costs as well as the inclusion of printed circuits that are used to place discrete passive components in the circuit.

Qualification costs 518 are incurred as specifications are passed down from the top of the supply chain Level 1 (Service Provider) 514 that determines the performance requirements of the product and the required processes, design and test procedures used in each level 512, 510, 508, 506, 504, down to Level 7 502 to assure a profitable and reliable product the sourcing and initial processing of Raw Materials up through the production of the finished End-User device 618. Level 7 Raw Materials Prep 502 manages the production of ceramic powders, organic polymers, and semiconductor precursor materials. Level 6 Component Production 504 manages the input of prepared raw materials and their conversion into components such as substrate interconnects, semiconductor die, passive circuit elements, and printed circuit boards. Level 5 Assembly and Packaging 506 configures those components for subsequent assembly steps. Level 4 Subsystem Modules 508 converts the packaged components into specialized circuit modules, like memory, radio, processor and power modules. Level 3 Final Assembly 510 manages the integration/assembly of subsystem modules into cell phones/smart devices, computers, satellites and base stations. Level 2 System Integrators 512 represent companies like Apple, Nokia, Dell, etc. that coordinated the functions of the entire supply chain 500. Level 1 Service Provider/Portal Company 514 define the performance specifications of products made by the Level 2 System Integrators 512 and resells them to Level 0 Mobile Subscriber 516.

In the United States through the 1990s, this supply chain was spread across the North American continent, so logistical costs that paid for the work product to move up the supply chain were high and soon became unaffordable when Foxconn co-located most elements of microelectronic supply chain 500 on large (60 acre campuses) that require 350 k laborers to move the work product from Level 7 (Raw Materials Prep) 502. Additional costs in the form of profit margins 520 are incurred when passing the work product up through the various supply chain levels when they are run by different business interests. The large production campuses set up by Foxconn consolidated those costs, but not achieve major production efficiencies that restructured the supply chain to achieve fundamental cost savings. For instance, up until the mid-1990s IBM managed the production of ceramic substrates. It managed the production of ceramic precursor powders over 3 days at a powder blend facility in Halsted, PA. The blended powders are then shipped to East Fishkill, NY where IBM managed final production of the substrates that included milling (starting on day 4), casting (day 7), blanking (day 13), punching (day 17), screening (day 20), stacking (day 25), sizing (day 30), sintering (day 35), thin films (day 45). This process ran 50+ days before being shipped to the customers on Level 5 Assembly and Packaging 506, accounting for almost 50% of the time-to-market costs of the final product sold to Level 0 Mobile Subscriber 516. Almost 25% of the work product was removed as it moved along this production line in order to achieve a production yield in excess of 95% with greatest labor dependency accounting for the multiple inspections need to achieve that production yield. The move to Asia served to lower labor costs, but it did not improve the production system that required thousands of laborers to monitor and manage more than 120 major control processes over 50+ days to manufacture products still located at the bottom of the supply chain.

Therefore, means that streamline COGS costs and restructure the microelectronic supply chain into a minimalist system with shorter throughput times to create products located higher up the supply/value chain are of great commercial value and economic benefit.

The semiconductor chip created great commercial value by shrinking the transistor element from the volume of a vacuum tube to microscopic dimensions and integrated them in large numbers into a single part for subsequent assembly. The first commercially successful semiconductor chip contained six transistor elements and its bill-of-material (BOM) cost was more than the six vacuum tubes it replaced, but the ability to integrate them as a single part so greatly reduced COGS charges (assembly, inventory, repair/inspection costs, etc.) that vacuum tubes were virtually displaced from the marketplace. Therefore, means that miniaturize and integrate all necessary circuit components (passive network filters) on a chip have great commercial value and economic benefit.

In the 1990's Nokia Research Japan Ltd. worked with the leading Japanese ceramics manufacturers on trying to integrate passive components into an RF Front-End. They concluded that could only be done profitably if the ceramic components maintained critical performance values, wherein their rated performance value was within 1% of the design value specified over all standard operating temperatures. Performance value of the majority of electroceramics has great variance with composition, grain size, time, applied voltage, temperature that prevent them from satisfying critical performance tolerances. Critical performance tolerances are only satisfied in electroceramic compositions with nanoscale microstructures, where all grains have identical composition and grain size that is less than or equal to 50 nm.

FIG. 9B illustrates the process used to integrate electroceramics within interposers or form passive elements on semiconductor die. LCD is the preferred deposition process to integrate passive components, semiconductors, and metallic species with amorphous or nanoscale microstructures. The first step reacts individual metals 525A,525B,525X to make stock solutions for individual metallic precursors 526A,526B,526X. This step in the process takes less than 1 hour to perform. The individual metallic precursors 525A,525B,525X are then filtered and assayed to determine a precise value for their molarities in an assayed stock solution, 528A,528B 528X. The assayed stock solutions 528A,528B 528X are then mixed 530 in calibrated amounts into a batch solution having a stoichiometry that will yield the desired composition with 0.0% compositional variance that is uniformly applied as a glassy/amorphous initial deposit 450 across a large area substrate 452 that is ≥6 inches in diameter after the spray deposition 532. When manufacturing products requiring line widths ≥25 μm mechanical masks can be used to pattern the sprayed initial deposit 450.

Spray deposition rates can achieve up to 25 μm-min⁻¹ when forming the initial deposit 450. The initial deposit 450 then undergoes a bake out step 534 to remove residual organics 454 from the initial deposit 450. The resulting clean deposit 456 is then subsequently plasma annealed 458 to produce the optimal microstructure (uniform grain size) for the deposited layer. Because of the robust chemical uniformity of LCD initial deposits 450, machine learning tools can be applied to automate the spray deposition 532, bake out step 534, and plasma annealing steps 458 in continuous loops 538. The automation and this degree of inherent uniformity allows products penetrating up the market value chain to power management devices to be made in volume with manufacturing throughput times as short as 2-4 hours. Products with finer line width specification require photolithographic processing that push manufacturing throughput times from 2 hours to 4 days. Since high-speed chip stacks with active thermal management can be made to comprise a complete microelectronic system, time-to-market costs of products made using the LCD process using methods shown in FIG. 9B are reduced by close to 97% when compared to products made using complex legacy supply chains 500.

The burden of supply chain management using the restructured supply chain 550 is reduced to verifying the purity of refined metals, the quality of the chemical solvents they are reacted with, and the known-good-die (KGD) of the wafers. Because electroceramics with nanoscale microstructure can be integrated with transistor elements embedded within semiconductor substrates heated to low temperatures that are ≤450 °C a restructured supply chain 550 comprises only four major levels: Level 0 (Consumer) 552, Level 2 (Service Provider/Portal Company) 554, Level 2 (System Integration) 556, which manages Design 558, and the production of integrated passive components 560 that comprise interposers and semiconductor die with integrated passive circuit elements. Level 3 (Raw Materials and IC Wafers) 562 manages the qualification of Raw Materials and Known-Good-Die on turned semiconductor wafers as primary factory inputs to Level 2 (System Integration) 556 that manufactures or designs and sources the high-speed chip stack with active thermal management 100.

The restructured supply chain 550 shares many attributes of the design model introduced when integrated transistor chips displaced vacuum tubes from electronic systems. A data interchange 564 provides essential manufacturing information (composition/processing recipes) to the Design 558 groups and the managers of manufactured goods related to Level 3 (Raw Materials and IC-Wafer) 562 and Integrated Components 560. Cost-of-Goods-Sold (COGS) charges 566 are now limited to qualification activities related to assuring design activity meets Level 1 (Service Provider/Portal Company) specifications. Excess Bill-of-Material (BOM) cost 568 related to profit margin stacking is limited to the absorption or raw materials and the production of IC-wafer 562 cost. Level 2 (System Integration) now capture the majority of profits derived from Design 558 activities, manufacturing Integrated Components 570 and passing the finished system 572 to Level 1 (Service Provider/Portal Companies).

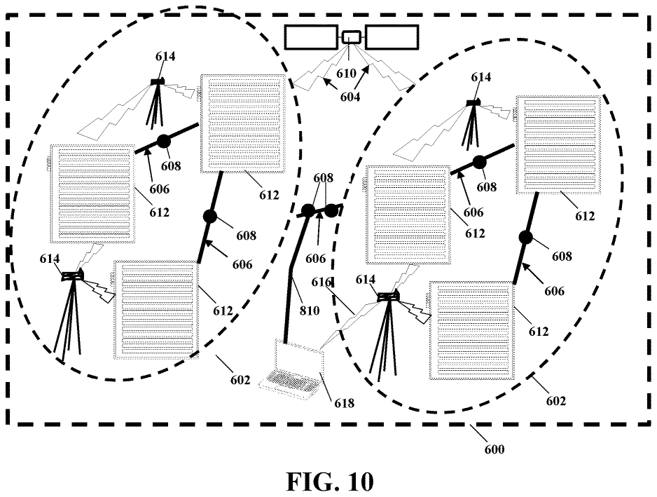

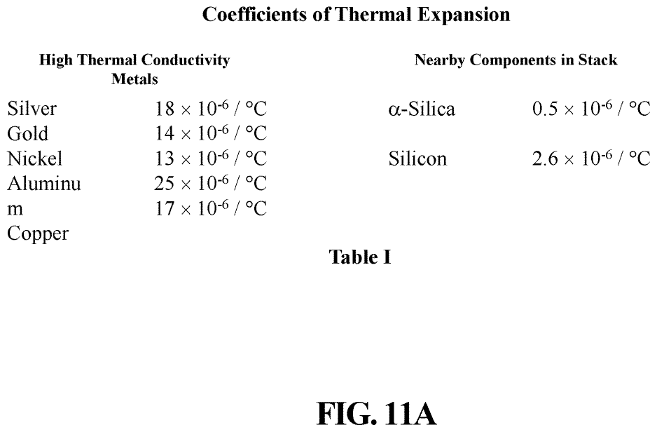

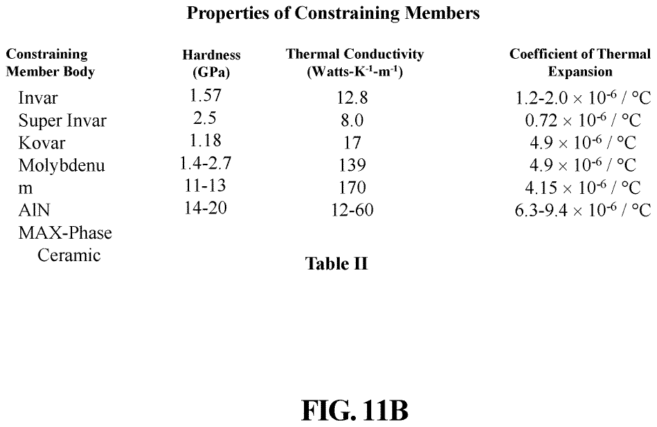

Reference is now made to FIG. 10 to illustrate the application scope of this invention within the global IT system 600 that comprises regional networks 602 interconnected by satellite communications links 604 and/or optical fiber telecommunications links 606. The high-speed chip stack with active thermal management 100 claimed herein increase processing speeds by reducing thermal throttling to create a more productive global IT system 600. Furthermore, since the high-speed chip stack with active thermal management 100 harvests waste heat and converts to useful electrical power it enables the global IT system 600 to become more power efficient. These benefits have great economic value to global IT operations, especially when providing energy intensive services like artificial intelligence, or mining or transacting crypto-currencies or other Blockchain services. Therefore, it is a preferred embodiment of this application to incorporate high-speed chip stacks with active thermal management 100 as circuit elements within the nodes or repeating stations 608 of optical fiber telecommunications links 606 and satellites 610 that connect regional networks 602 within the global IT system 600. Similarly, it is an additional preferred embodiment to incorporate high-speed semiconductor chip stacks with active thermal management 100 as circuit elements within server farms 612 and wireless network nodes 614 that link 616 end-user devices 618 to regional networks 602 and the global IT system 600. End-user devices 618 may also utilize direct optical networks 620 comprising nodes with high-speed chip stacks with active thermal management 100 and satellite links 604 to interact with regional networks 602 and the global IT system 600.

All patents, published applications, and references mentioned herein are hereby incorporated by reference in their entirety as if each individual patent, published application, or reference was specifically and individually indicated to be incorporated by reference. In case of conflict, the present application, including any definitions herein, will control.

While specific aspects and embodiments of the subject disclosure have been discussed, the above specification is illustrative and not restrictive. Many variations of the disclosure will become apparent to those skilled in the art upon review of this specification and the claims below. The full scope of the disclosure should be determined by reference to the claims, along with their full scope of equivalents, and the specification, along with such variations.

While example embodiments have been particularly shown and described, it will be understood by those skilled in the art that various changes in form and details may be made therein without departing from the scope of the embodiments encompassed by the appended claims.

What is claimed:

1. A fully integrated inverter module comprising a ground plane connection, an array of resistive electroceramics selectively deposited on the ground plane connection, an overlay of amorphous silica covering the p the array of resistive elements and partially covering the ground plane connection that is polished to expose the selectively deposited array of resistive electroceramics ant do create a smooth surface on the amorphous silica insulator with the array of electroceramic resistive elements such that additional semiconductor material can be deposited thereon to form power transistors, further comprising vertical electrical connections through an additional amorphous silica layer separating the ground plane from a toroidal enter-tapped transformer coil wherein the primary coil winding are wound serial electrical connection and the secondary coil windings are configured in parallel connection to determine the performance rating of the transformer, such that the center-tap electrical connection provides DC voltage input to the fully integrated inverter circuit, and vertical connections to the parallel would coil secondary oil make electrical connection to the inverter module output, wherein electrical connections are made Resonant Gate Power Transistors formed on the additional material and additional capacitive electroceramic material is formed on the overlay of amorphous silica insulator and electrically conductive elements provide electrical connection between the capacitive electroceramic, the resistive electroceramic, and the Resonant Gate Power Transistors to form the Inventor Module's Wiggler Circuit.

2. The fully integrated inverter module as in claim 1 wherein the additional semiconductor material comprises a polycrystalline semiconductor wherein all the crystalline grains have identical chemical composition and uniform size that is less than or equal to 50 nm.

3. The fully integrated inverter module as in claim 2, wherein the resistive electroceramic comprises crystal structure and typically contain the following metal oxides as a primary component: copper oxide (CuO), nickel oxide (NiO), ruthenium oxide (RuO₂), irdium oxide (IrO₂), rhodium oxide (Rh₂O₃), osmium oxide (OsO₂), and antimony oxide (Sb₂O₃). This group of primary metal oxides comprises the group of preferred electroceramic compositions. These single component resistive electroceramics adopt a rutile crystal structure, with the exception of antimony oxide (Sb₂O₃) and rhodium oxide (Rh₂O₃), which have a trigonal crystal structures, and copper oxide (CuO) and nickel oxide (NiO), which have a cubic close-packed crystal structure. Intrinsic resistivity of the primary metal oxides with rutile crystal structures can be altered when the rutile primary oxides are combined together and with one or more transition-metal oxides and/or heavy-metal oxides in amounts that crystallize into a pyrochlore crystal structure. Intrinsic resistivity of the primary metal oxides with rutile crystal structures can also be altered when the rutile primary oxides are combined together and with one or more alkaline earth metal oxides and heavy-metal oxides in amounts that crystallize into a perovskite crystal structurecrystal structure and typically contain the following metal oxides as a primary component: copper oxide (CuO), nickel oxide (NiO), ruthenium oxide (RuO₂), irdium oxide (IrO₂), rhodium oxide (Rh₂O₃), osmium oxide (OsO₂), and antimony oxide (Sb₂O₃). This group of primary metal oxides comprises the group of preferred electroceramic compositions. These single component resistive electroceramics adopt a rutile crystal structure, with the exception of antimony oxide (Sb₂O₃) and rhodium oxide (Rh₂O₃), which have a trigonal crystal structures, and copper oxide (CuO) and nickel oxide (NiO), which have a cubic close-packed crystal structure wherein the intrinsic resistivity of the primary metal oxides with rutile crystal structures can be altered when the rutile primary oxides are combined together and with one or more transition-metal oxides and/or heavy-metal oxides in amounts that crystallize into a pyrochlore crystal structure and the intrinsic resistivity of the primary metal oxides with rutile crystal structures can also be altered when the rutile primary oxides are combined together and with one or more alkaline earth metal oxides and heavy-metal oxides in amounts that crystallize into a perovskite crystal structure

4. The fully integrated inverter module as in claim 3, wherein the capacitive electroceramic comprises a uniform distribution of grains size 50 nm or less that have average atomic mass units (amu) in excess of 25 amu, preferably in excess of 50 amu, wherein the polarization response is limited to the deformation of atomic orbitals.

5. The fully integrated inverter module, as in claim 4, wherein the atomic mass unit (amu) it the storage capacitors comprise high energy density dielectric layers with or more metal oxide components further comprising a titanate perovskite electroceramic satisfying the following is formula equation: M^{(I)}_{(1-x-y-z)}M^{(II)}₍ₓ₎M^{(III)}_{(y)}M^{(IV)}_{(z)}Zr_{(1-a-b)}Hf_{(b)}Ti₍ₐ₎O₃, where M^{(I)}, M^{(II)}, M^{(III)}, M^{(IV)} are additional metal oxide components that form a thermodynamically stable perovskite crystal and the same general relationship applies to niobate and tantalate electroceramics, and that higher average amu is achieved by incorporating higher amu elements in the perovskite chemical formula.

6. The Fully Integrated Inverter as in claim 5 that comprises a perovskite electroceramic that includes three or more metal oxide components that further comprise an admixture of three (3) or more of the elements additionally consisting of Scandium (Sc), Titanium (Ti), Vanadium (V), Chromium (Cr), Zinc (Zn), Zirconium (Zr), Molybdenum (Mo), Hafnium (Hf), Tantalum (Ta) and Tungsten (W), and lanthanide elements consisting of Lanthanum (La), Cerium (Ce), Praseodymium (Pr), Neodymium (Nd), Europium (Eu), Gadolymium (Gd), Terbium (Tb), Dysprosium (Dy), Holmium (Ho), Ytterbium (Yb) and post transition metal elements consisting of Indium (In), Tin (Sn), Lead (Pb) and Bismuth (Bi).

7. A composite ferromagnetic core as in claim 6, used in magnetic circuits that relate to fully integrated inverter power inverter modules in DC motors electric motors wherein the composite ferromagnetic core has high relative magnetic permeability, μᵣ, desirable in electromagnet applications because of because of their ability to generate higher linkage flux densities, φ₁, that perform the work in electrical motor drives by embedding composite structures comprising extreme resistance amorphous silica layered elements having thickness between 20 nm and 50 nm. A composite ferromagnetic core used in magnetic circuits that relate to fully integrated inverter power inverter modules in DC motors electric motors wherein the composite ferromagnetic core has high relative magnetic permeability, μᵣ, desirable in electromagnet applications because of because of their ability to generate higher linkage flux densities, φ₁, that perform the work in electrical motor drives by embedding composite structures comprising extreme resistance amorphous silica layered elements having thickness between 20 nm and 50 nm.

8. A composite ferromagnetic core as in claim 7, wherein the composite ferromagnetic core comprises Mumetals (Fe₁₇Ni₅₆Cu₅Cr₂) with 80% Nickel Alloy and further comprises layered amorphous silica elements. A composite ferromagnetic core wherein the composite ferromagnetic core comprises Mumetals (Fe₁₇Ni₅₆Cu₅Cr₂) with 80% Nickel Alloy and further comprises layered amorphous silica elements.

9. A composite ferromagnetic core as in claim 8, wherein the composite ferromagnetic core comprises Mumetals (Fe₁₇Ni₅₆Cu₅Cr₂) with 80% Nickel Alloy and further comprises layered amorphous silica elements.

10. A composite ferromagnetic core as in claim 9 wherein the composite ferromagnetic core comprises Mumetals (Fe₁₇Ni₅₆Cu₅Cr₂) with 80% Nickel Alloy and further comprises layered amorphous silica elements.

11. A composite ferromagnetic core as in claim 10, wherein the composite ferromagnetic core comprises Mumetals (Fe₁₇Ni₅₆Cu₅Cr₂) with 49% Nickel Alloy and further comprises layered amorphous silica elements and a loss tangent of 10⁻⁴<tan δ<10⁻⁵.

12. A composite ferromagnetic core as in claim 11 wherein the composite ferromagnetic core comprises Iron Alloy and further comprises layered amorphous silica elements and a loss tangent of 10⁻⁴<tan δ<10⁻⁵.

13. A composite ferromagnetic core as in claim 12 wherein the composite ferromagnetic core comprises Supermalloy and further comprises layered amorphous silica elements and a loss tangent of 10⁻⁴<tan δ<10⁻⁵.

14. A composite ferromagnetic core as in claim 13, wherein the composite ferromagnetic core comprises Mumetals (Fe₁₇Ni56Cu5Cr₂) with 49% Nickel Alloy and further comprises layered amorphous silica comprising one or more of the following alloying elements: Copper, (Cu), Chromium (Cr), Molybdenum (Mo), Zinc (Zn), Silicon (Si), Cobalt (Co), Phosphorous (P), Boron (B), Tantalum (Ta), Niobium (Nb) or Zirconium (Zr) A composite ferromagnetic core wherein the composite ferromagnetic core comprises Mumetals (Fe₁₇Ni56Cu5Cr₂) with 49% Nickel Alloy and further comprises layered amorphous silica comprising one or more of the following alloying elements: Copper, (Cu), Chromium (Cr), Molybdenum (Mo), Zinc (Zn), Silicon (Si), Cobalt (Co), Phosphorous (P), Boron (B), Tantalum (Ta), Niobium (Nb) or Zirconium (Zr)

15. An electromagnet as in claim 14 comprising a composite ferromagnetic core further comprising conductive means windings wrapped around the central axis of the electromagnet wherein extreme resistance layered amorphous silica is used as a cladding layer to the conductive means that is 25-50 micron in thickness and wrapped around the ferromagnetic core which has microstructure wherein all grain have identical compositional chemistry and uniform grain size ranging between 5-7 μm in diameter.

16. An electromagnet as in claim 15, that comprises a layer of extreme resistivity amorphous silica that has a loss tangent in the range of tan δ=10⁻⁴ to 10⁻⁵, resistivity ρ≈10¹⁸ Ω-cm, and dielectric breakdown voltage on the order of 10 MegaVolts-cm-1 or 1,000 V-μm, wherein the electromagnet is electrically coupled to a fully integrated inverter module to form a stator. electromagnet that comprises a layer of extreme resistivity amorphous silica that has a loss tangent in the range of tan δ=10⁻⁴ to 10⁻⁵, resistivity ρ≈10¹⁸ Ω-cm, and dielectric breakdown voltage on the order of 10 MegaVolts-cm-1 or 1,000 V-μm, wherein the electromagnet is electrically coupled to a fully integrated inverter module to form a stator.

17. A plurality of electromagnets as in claim 16 comprising layers of extreme resistivity amorphous silica located in their flux linkage areas of the plurality of the electromagnets and anti-ferromagnetic layers are located to maximize linkage flux in flux linkage areas are electrically attached to the fully integrated inverter module so as to generate opposing field polarities rotate a rotor within an DC electric powered induction motor when magnetically coupled to a rotor.

18. The DC electrically powered induction motor as in claim 17 that operates in synchronous or a synchronous mode.

19. A rotor comprising a plurality of composite ferromagnetic core as in claim 18 used for Permanent Applications configured in opposing polarities with extreme resistance and antiferromagnetic layers that maximize linkage flux between the rotor and the stator when magnetic coupled to a plurality of composite ferromagnetic cores used for electromagnet applications that function as s stator when electrically coupled to the fully integrated inverter module that drives the rotor in a DC powered motor. A rotor comprising a plurality of composite ferromagnetic core used for Permanent Applications configured in opposing polarities with extreme resistance and antiferromagnetic layers that maximize linkage flux between the rotor and the stator when magnetic coupled to a plurality of composite ferromagnetic cores used for electromagnet applications that function as s stator when electrically coupled to the fully integrated inverter module that drives the rotor in a DC powered motor.
